(19) United States
(12) Patent Application Publication
(10) Pub. No.: US 2025/0305118 A1
(43) Pub. Date: Oct. 2, 2025

(54) METHODS AND SYSTEMS FOR FORMING HIGHLY CONFORMAL AND LOW RESISTIVITY VANADIUM NITRIDE THIN FILMS

(71) Applicant: Eugenus, Inc., San Jose, CA (US)

(72) Inventors: Antony Kim Amur Jan, Morgan Hill, CA (US); Hae Young Kim, San Jose, CA (US); Sang-Hyeob Lee, Fremont, CA (US); Kyuho Cho, Suwon-si (KR); Sun Young Baik, Suwon-si (KR)

(21) Appl. No.: 19/093,945

(22) Filed: Mar. 28, 2025

Related U.S. Application Data
(60) Provisional application No. 63/572,851, filed on Apr. 1, 2024.

(51) Int. Cl. C23C 16/34; C23C 16/455; C23C 16/52

(52) U.S. Cl. CPC C23C 16/34; C23C 16/45553; C23C 16/52

(57) ABSTRACT

The disclosed technology relates generally to semiconductor manufacturing, and more particularly to precursor delivery in cyclic deposition of vanadium nitride thin films. In one aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in the canister by sequentially opening the first and second valves. The method additionally comprises disposing the substrate in the thin film deposition chamber and alternatingly exposing the substrate to the vaporized vanadium precursor and a nitrogen precursor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119 (e) to U.S. Provisional Patent Application No. 63/572,851, filed Apr. 1, 2024, entitled “METHODS AND SYSTEMS FOR FORMING HIGHLY CONFORMAL AND LOW RESISTIVITY VANADIUM NITRIDE THIN FILMS,” the content of which is hereby expressly incorporated by reference in its entirety.

### BACKGROUND

### Field

The disclosed technology relates generally to semiconductor manufacturing, and more particularly to vanadium nitride thin films and methods and systems for depositing the same.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited throughout the process flow. Various thin films can be deposited using different techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD).

### SUMMARY

In a first aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in the canister by sequentially opening the first and second valves. The method additionally comprises disposing the substrate in the thin film deposition chamber and alternatingly exposing the substrate to the vaporized vanadium precursor and a nitrogen precursor.

In a second aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in the canister such that a partial pressure of Cl₂ in the thin film deposition chamber resulting from a decomposition of the liquid vanadium precursor is less than 1 mTorr. The method additionally comprises disposing the substrate in the thin film deposition chamber and alternatingly exposing the substrate to the vaporized vanadium precursor and a nitrogen precursor.

In a third aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in the canister that has not been used for deposition for at least one day. The method additionally comprises disposing the substrate in the thin film deposition chamber and alternatingly exposing the substrate to the vaporized vanadium precursor and a nitrogen precursor.

In a fourth aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in a plurality of steps, wherein each step removes a sub-portion of the portion of the volume. The method additionally comprises disposing the substrate in the thin film deposition chamber and alternatingly exposing the substrate to the vaporized vanadium precursor and a nitrogen precursor.

In a fifth aspect, a method of depositing a vanadium nitride thin film comprises providing a thin film deposition system comprising a vanadium precursor delivery line comprising first and second valves disposed between a final valve and a vanadium precursor source comprising a canister including a liquid vanadium precursor and a volume of gas including vaporized vanadium precursor. The method additionally comprises conditioning the vanadium precursor source, without a substrate in a thin film deposition chamber, by controllably removing a portion of the volume of gas in the canister while monitoring one or both of a pressure and a composition of the volume of gas. The method additionally comprises disposing the substrate in the thin film deposition chamber and alternatingly exposing the substrate to the vaporized vanadium precursor and a nitrogen precursor.

In a sixth aspect, a method of depositing a vanadium nitride thin film comprises providing a thin film deposition system comprising a high conductance reservoir portion as part of a vanadium precursor delivery line connected to a vanadium precursor source comprising a canister including a liquid vanadium precursor and a volume of gas including vaporized vanadium precursor. The high conductance reservoir portion is elongated in a flow direction and has a conductance that is at least four times greater than either of immediately adjacent low conductance line portions connected at opposing ends of the high conductance reservoir portion. The method additionally includes alternatingly exposing a substrate in a thin film deposition chamber to the vaporized vanadium precursor and a nitrogen precursor. Exposing the substrate to the vaporized vanadium precursor comprises pressurizing the high conductance reservoir portion with a final valve closed, and opening the final valve for a duration and at a flow rate such that a pressure within the high conductance reservoir portion falls by less than 10% relative to the pressure within the high conductance reservoir portion prior to opening the final valve.

In a seventh aspect, a method of depositing a vanadium nitride thin film comprises providing a thin film deposition system comprising a high conductance reservoir portion as part of a vanadium precursor delivery line connected to a vanadium precursor source comprising a canister including a liquid vanadium precursor and a volume of gas including vaporized vanadium precursor. The high conductance reservoir portion is elongated in a flow direction and comprises a pressure gauge for monitoring the pressure therein. The method additionally includes alternatingly exposing a substrate in a thin film deposition chamber to the vaporized vanadium precursor and a nitrogen precursor. Exposing the substrate to the vaporized vanadium precursor comprises pressurizing the high conductance reservoir portion to a pressure exceeding 30 Torr with a final valve closed, and opening the final valve to expose the substrate to the vaporized vanadium precursor.

In an eighth aspect, a method of depositing a vanadium nitride thin film comprises providing a thin film deposition system comprising a high conductance reservoir portion as part of a vanadium precursor delivery line connected to a vanadium precursor source comprising a canister including a liquid vanadium precursor and a volume of gas including vaporized vanadium precursor. The high conductance reservoir portion is elongated in a flow direction and comprises a gas composition monitor. The method additionally includes alternatingly exposing a substrate in a thin film deposition chamber to the vaporized vanadium precursor and a nitrogen precursor. Exposing the substrate to the vaporized vanadium precursor comprises measuring a concentration of one or more gas species in the high conductance reservoir portion with a final valve closed, and opening the final valve to expose the substrate to the vaporized vanadium precursor upon determining that the concentration is within a threshold range.

In a ninth aspect, a method of depositing a vanadium nitride thin film comprises providing a thin film deposition system comprising a vanadium precursor delivery line connected to a vanadium precursor source comprising a canister including a liquid vanadium precursor and a gas including vaporized vanadium precursor and a carrier gas, wherein the vanadium precursor delivery line comprises a metering valve limiting a flow of the gas to a thin film deposition chamber. The method additionally includes alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a substrate temperature of 300-800° C.; an exposure duration to the gas including the vaporized vanadium precursor of 20 ms to 2 s; a flow rate of the carrier gas greater than 100 sccm; and a flow coefficient (Cᵥ) of the metering valve set to a value greater than 0.002.

In a tenth aspect, a method of depositing a vanadium nitride thin film comprises providing a thin film deposition system comprising a vanadium precursor source comprising a canister including a liquid vanadium precursor heated to a temperature of 30 to 150° C. and a gas including vaporized vanadium precursor and a carrier gas flowing therethrough. The method additionally comprises alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a substrate temperature of 300-800° C.; an exposure duration to the gas including the vaporized vanadium precursor of 20 ms to 2 s; and a flow rate of the carrier gas greater than 200 sccm.

In an eleventh aspect, a method of depositing a vanadium nitride thin film comprises providing a thin film deposition system comprising a vanadium precursor source comprising a canister including a liquid vanadium precursor and a gas including vaporized vanadium precursor and a carrier gas flowing therethrough. The method additionally comprises alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a substrate temperature of 300-800° C.; an exposure duration to the gas including the vaporized vanadium precursor of 500 ms to 2 s; and a flow rate of the carrier gas greater than 100 sccm.

In a twelfth aspect, a method of depositing a vanadium nitride thin film comprises providing a thin film deposition system comprising a vanadium precursor source comprising a canister including a liquid vanadium precursor and a gas including vaporized vanadium precursor and a carrier gas flowing therethrough. The method additionally comprises alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a partial pressure of Cl₂ in the thin film deposition chamber resulting from a decomposition of the liquid vanadium precursor less than 1 mTorr; a substrate temperature of 300-800° C.; an exposure duration to the gas including the vaporized vanadium precursor of 20 ms to 2 s; and a flow rate of the carrier gas greater than 100 sccm.

In a thirteenth aspect, a method of depositing a vanadium nitride thin film comprises providing a thin film deposition system comprising a vanadium precursor source comprising a canister including a liquid vanadium precursor and a gas including vaporized vanadium precursor and a carrier gas flowing therethrough. The method additionally includes providing in a thin film deposition chamber a patterned substrate comprising a plurality of trenches or vias having an aspect ratio exceeding 10 and an opening width smaller than 100 nm. The method additionally comprises alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a substrate temperature of 300-800° C.; an exposure duration to the gas including the vaporized vanadium precursor of 20 ms to 2 s; and a flow rate of the carrier gas greater than 100 sccm. A step coverage, defined as a ratio of a thickness of the thin film at a lower half of a sidewall of the trenches or vias to a thickness of the thin film at an upper half of the sidewall of the high aspect ratio trench or via, that is higher than 30%.

In some embodiments, conditioning is such that a partial pressure of Cl2 in the thin film deposition chamber resulting from a decomposition of the liquid vanadium precursor is less than 1 mTorr. In some embodiments, the canister has not been used for deposition for at least one day. In some embodiments, the first valve is closer to the vanadium precursor source and the second valve is farther from the vanadium precursor source relative to the first valve, and wherein conditioning comprises opening the first valve while keeping the second valve closed, followed by closing the first valve to enclose the portion of the volume of gas between the first and second valves, followed by opening the second valve while keeping the first valve closed to pump out the portion of the volume of gas through a foreline. In some embodiments, the nitrogen precursor comprises NH₃.

In some embodiments, controllably removing the portion of the volume of gas comprises sequentially opening the first and second valves a plurality of times. In some embodiments, controllably removing a portion of the volume of gas comprises removing in a plurality of steps, wherein each step removes a sub-portion of the portion of the volume. In some embodiments, controllably removing the portion of the volume of gas in the canister is performed while monitoring one or both of a pressure and a composition of the volume of gas. In some embodiments, controllably removing the portion of the volume of gas comprises removing until the pressure of less than 100 Torr is detected between the first and second valves. In some embodiments, controllably removing the portion of the volume of gas comprises removing until the pressure is less than 10% of an initial pressure prior to controllably removing the volume of gas. In some embodiments, controllably removing the portion of the volume of gas comprises removing until a predetermined composition is detected.

In some embodiments, the first valve is closer to the vanadium precursor source and the second valve is farther from the vanadium precursor source relative to the first valve, wherein the method further comprises monitoring one or both of a pressure and a concentration of the gas between the first and second valves with the second valve closed.

In some embodiments, controllably removing the portion of the volume of gas comprises removing until a predetermined partial pressure of Cl2 is detected between the first and second valves. In some embodiments, controllably removing the portion of the volume of gas comprises removing until the partial pressure of Cl₂ is less than 10% of an initial partial pressure of Cl₂ prior to controllably removing the volume of gas. In some embodiments, controllably removing the portion of the volume of gas comprises removing until the partial pressure of Cl2 in the thin film deposition chamber resulting from the decomposition of the liquid vanadium precursor is less than 0.25 mTorr. In some embodiments, the liquid vanadium precursor comprises VCl₄ in liquid form and the volume of gas further comprises Cl₂ resulting from a decomposition of VCl₄ in the canister for at least one day. In some embodiments, the concentration measured within the enclosed volume includes one or both of VCl₄ and Cl₂ concentrations. In some embodiments, controllably removing the portion of the volume of gas comprises removing until a predetermined concentration of VCl₄ is detected. In some embodiments, controllably removing the portion of the volume of gas comprises removing until a predetermined concentration of Cl₂ is detected.

### BRIEF DESCRIPTION OF THE DRAWINGS

FIG. 1 schematically illustrates a thin film deposition system including a thin film deposition chamber and a precursor delivery system configured with precursor delivery lines including high conductance line portions, according to embodiments.

FIG. 2A shows a perspective view of a lid portion of a deposition chamber comprising multiple processing stations that is configured to introduce precursors through conventional precursor delivery lines.

FIG. 2B shows a perspective view of a lid portion of a deposition chamber comprising multiple processing stations that is configured to introduce precursors through precursor delivery lines having high conductance line portions, according to embodiments.

FIG. 2C shows a perspective view of the precursor delivery lines having high conductance line portions for the deposition chamber illustrated in FIG. 2B.

FIG. 2D is a flow chart illustrating a method of depositing a vanadium nitride thin film using the thin film deposition system including a thin film deposition chamber and a precursor delivery system configured with precursor delivery lines including high conductance line portions, according to embodiments.

FIG. 3 is an experimental graph showing precursor volumes delivered to a process chamber with successive exposure pulses for different high conductance line portions having different volumes.

FIGS. 4A and 4B show experimental measurements of pressure changes in the precursor delivery lines, with and without a high conductance line portion, respectively, upon opening an atomic layer deposition (ALD) valve to introduce the precursor into the thin film process chamber.

FIG. 5A1 illustrates a liquid precursor delivery system for delivering a vaporized vanadium precursor into a thin film deposition chamber including a precursor conditioning system, according to embodiments.

FIG. 5A2 is a graph showing the flow coefficient of a metering valve that can be used to control the flow of the vaporized vanadium precursor.

FIG. 5B is a flow chart illustrating a method of depositing a vanadium nitride thin film including precursor conditioning, according to embodiments.

FIG. 5C is a flow chart illustrating a method of conditioning a vanadium precursor source, according to embodiments.

FIG. 5D is a flow diagram illustrating a method of conditioning a vanadium precursor source, according to embodiments.

FIG. 5E illustrates an example of experimental monitoring during conditioning of a vanadium precursor source to determine if the liquid precursor source is ready for use, according to embodiments.

FIG. 6 schematically illustrates an example precursor delivery sequence for delivering precursors using the precursor delivery system according to embodiments.

FIG. 7A is an experimental graph of thickness-dependent resistivity and sheet resistance of a vanadium nitride thin film deposited at 430° C., according to embodiments.

FIG. 7B is an experimental graph of thickness-dependent resistivity and sheet resistance of a vanadium nitride thin film deposited at 550° C., according to embodiments.

FIG. 8 is a grazing incidence X-ray diffraction spectra of a vanadium nitride thin film deposited according to embodiments, measured at various substrate locations.

FIG. 9A shows a lower magnification cross-sectional transmission electron micrograph of a vanadium nitride thin film deposited according to embodiments.

FIG. 9B shows a high-resolution cross-sectional transmission electron micrograph of a vanadium nitride thin film deposited according to embodiments.

FIG. 9C shows a Fourier transform of a dark field transmission electron micrograph of a vanadium nitride thin film deposited according to embodiments.

FIG. 10 schematically illustrates a cross-sectional view of a via or trench lined with a vanadium nitride thin film layer having different thicknesses at different portions thereof.

FIG. 11A illustrates cross-sectional transmission micrographs of vanadium nitride thin film deposited in high aspect ratio structures at various process conditions, according to embodiments.

FIG. 11B illustrates cross-sectional transmission micrographs of vanadium nitride thin film deposited in high aspect ratio structures at various process conditions and corresponding step coverage values, according to embodiments.

FIG. 11C is a summary table of measured step coverage values of vanadium nitride thin film deposited in high aspect ratio structures for various process conditions, according to embodiments.

FIG. 12A schematically illustrates cross-sectional view of a vanadium nitride thin film formed as a top electrode of a capacitor, according to embodiments.

FIG. 12B schematically illustrates a cross-sectional view of a vanadium nitride thin film formed as a bottom electrode of a capacitor, according to embodiments.

FIG. 13 schematically illustrates a cross-sectional view of a vanadium nitride thin film formed as buried wordlines, according to embodiments.

FIG. 14 schematically illustrates a vanadium nitride thin film forming high aspect ratio bitlines of a three-dimensional memory array structure, according to embodiments.

FIG. 15A shows experimental measurements related to impact of pressure without rapid purge on within-wafer uniformity for VN thin films, according to embodiments.

FIGS. 15B and 15C show experimental measurements related to impact of rapid purge on within-wafer uniformity for VN thin films, according to embodiments.

### DETAILED DESCRIPTION

As feature sizes continue to scale in semiconductor process architectures, thin film properties must also correspondingly improve. For example, as the lateral footprint of dynamic random access memory capacitors shrinks, aspect ratios of capacitors become increasingly aggressive. In turn, there is an increasing need for the component thin films, such as electrodes, to improve in many aspects, including resistivity, roughness, deposition temperature and conformality, to name a few.

Among various materials, metal nitrides (MNₓ, where M can be Ti, Ta, Hf, V, to name a few) play a critical role in semiconductor process architectures. For example, TiN has been a key material to serve various functions in CMOS integration, including diffusion barriers and electrodes. As process technology nodes continue to advance, e.g., sub-20 nm, intrinsic properties of TiN may not be sufficient for some applications. Thus, there is a need for novel metal nitride.

Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., Yba₂Cu₃O₇₋ₓ), and chalcogenides (e.g., GeSbTe), to name a few.

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. Because of the layer-by-layer growth capability, ALD can enable precise control of the thickness and the composition, which in turn can enable precise control of various properties such as conductivity, conformality, uniformity, barrier properties and mechanical strength. Because of the nature of deposition process in ALD, the precursor delivery systems of ALD deposition systems face unique challenges compared to, e.g., the precursor delivery systems of CVD deposition systems. For example, because the alternating exposures of the substrate to multiple precursors are repeatedly carried out at a relatively high speed and/or at a relatively high frequency, precursor delivery systems or components thereof such as precursor delivery lines valves can directly or indirectly pose significant limitations to various aspects of the ALD deposition processes, including precision, throughput, reliability and operating cost thereof. Because deposition of a thin film by ALD may involve from few to as much as thousands of cycles of alternating exposures to different precursors, the numbers, durations and frequencies of the alternating exposures of the substrate to multiple precursors is directly proportional to the throughput. The numbers, durations and frequencies of the exposures can in turn be limited by the precursor delivery system or components thereof, such as precursor delivery line configurations. In particular, the conductance, volume and pressure stability of the precursor delivery lines can directly impact deposition throughput, the efficiency of precursor use and the quality of the resulting thin film. Thus, there is a need for improved precursor delivery systems having fast valves and delivery lines adapted for high conductance, high volume and high pressure stability for increased throughput as well as improved film properties such as high step coverage, conformality and uniformity.

Precursor Delivery System with High Conductance Precursor Reservoirs for Fast Throughput Deposition of Vanadium Nitride

To address the above-mentioned needs among others, a thin film deposition system comprises a thin film deposition chamber configured to deposit a thin film by alternatingly exposing a substrate to a plurality of precursors. The thin film deposition system further comprises a precursor source connected to the thin film deposition chamber by a precursor delivery line. The precursor delivery line comprises an increased or high conductance line portion serving as an intermediate precursor reservoir disposed between the precursor source and the thin film deposition chamber. The configuration allows for higher dosage of precursors per cycle that the substrate is exposed to in the process chamber, which in turn can lead to a substantial reduction in precursor exposure times to reach substantial substrate surface saturation by the precursors. The configuration also allows for increased stability of the precursors delivered into the process chamber. For example, the configuration allows for increased dosage with reduced pressure fluctuation in the delivery lines by providing an intermediate precursor reservoir serving as a high conductance buffer between the thin film deposition chamber and the precursor sources. The configuration can be especially advantageous for process chambers having multiple process stations, which can use much higher amounts of precursors and purge gases. The increased dosage and stability of the precursors delivered by the precursor delivery system according to embodiments advantageously enables improved step coverage and uniformity of the thin film in high aspect ratio structures.

As described herein, a high conductance line portion refers to a delivery line portion that is elongated in a flow direction with first and second ends serving as inlet and an outlet, respectively. The high conductance line portion has a conductance or volume per length that is greater relative to adjacent line portions connected to both ends thereof. For example, the high conductance line portion can have a cylindrical shape, where the length is greater than the diameter. The inventors have found that this configuration of the high conductance line portion is advantageous in serving as an intermediate reservoir while optimizing the conductance of the gas flowing therethrough. For example, while a reservoir or a tank in which the inlet and the outlet are disposed on the same side may serve as a reservoir, such configuration may lower the conductance of the gas passing therethrough.

As described herein, an atomic layer deposition (ALD) valve refers to a precursor delivery valve configured for introducing a precursor into an ALD deposition chamber in pulses with high precision and speed (e.g., a response time less than 30 ms) while having a high flow coefficient (e.g., Cᵥ exceeding 0.20). Because deposition of a thin film by ALD may involve from few to as much as thousands of cycles of alternating exposures to different precursors, valve parameters such as the flow rate, speed and/or frequency of the ALD valves can directly impact deposition throughput as well as the efficiency of precursor use. In addition, the wear of ALD valves can limit the service life of some ALD systems between preventive maintenance services. Some precursors, which are delivered at elevated temperatures, can further limit the throughput and service life of some ALD systems.

In the following, embodiments may be described using specific precursors. For example, specific examples precursors including VCl₄ and NH₃ for depositing VN may be used to describe the thin film deposition system of a method of depositing a thin film. However, it will be understood that embodiments are not so limited, and the inventive aspects can be applied to any suitable combination of precursors for depositing VN that can be formed using cyclic deposition processes such as ALD.

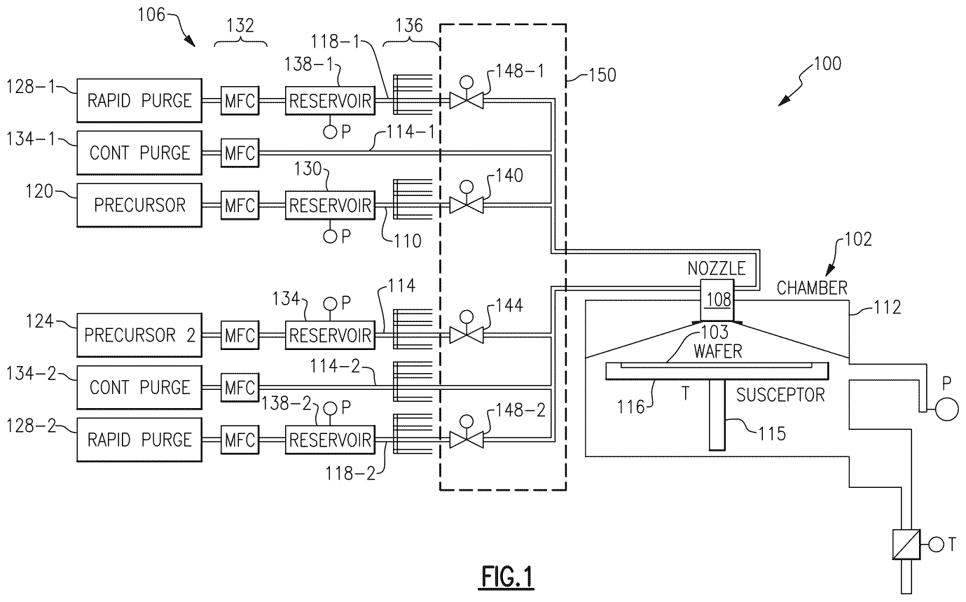

FIG. 1 schematically illustrates a thin film deposition system including a thin film deposition chamber and a precursor delivery system configured with precursor delivery lines including high conductance line portions, according to embodiments. The thin film deposition system 100 includes a thin film deposition chamber 102 and a precursor delivery system 106 configured to deliver a plurality of precursors into the deposition chamber 102. The illustrated deposition chamber 102 is configured to process a substrate 103, e.g., a wafer, on a support 116, e.g., a susceptor, that is supported by a supporting post 115, under a process condition. The deposition chamber 102 additionally includes a nozzle 108 configured to centrally discharge the plurality of precursors into the deposition chamber 102 through a gas distribution plate 112, also referred to as a showerhead. The nozzle 108 may mix gases, e.g., a precursor and a purge gas, prior to being diffused into the deposition chamber 102 by the gas distribution plate 112. The gas distribution plate 112 is configured to uniformly diffuse the precursor(s) over the substrate 103 on the support 116, e.g., a susceptor, so that a uniform deposition occurs. The deposition chamber may be equipped with pressure monitoring sensors (P) and/or temperature monitoring sensors (T).

The precursor delivery system 106 is configured to deliver a plurality of precursors from precursor sources (120, 124) and one or more purge gases, e.g., inert gases, from purge gas sources (128-1, 128-2, 134-1, 134-2) into the process chamber. Each of the precursors and purge gases is connected to the deposition chamber 102 by a respective gas delivery line. Advantageously, at least some of the gas delivery lines comprise increased conductance line portions serving as intermediate gas reservoirs between the precursor or purge gas sources and the thin film deposition chamber 102. The gas delivery lines additionally include in their paths mass flow controllers (MFCs) 132 and respective precursor valves for introducing respective precursors into the thin film deposition chamber. Further advantageously, at least some of the valves can be atomic layer deposition (ALD) valves. The gas delivery lines are connected to the deposition chamber 102 through the gas distribution plate 112.

For illustrative purposes only, in the illustrated configuration of FIG. 1, the plurality of precursors include a first precursor and a second precursor. The first precursor is stored in at least one first precursor source 120, and the second precursor is stored in at least one second precursor source 124. The precursor delivery system 106 is configured to deliver the first and second precursors from the first and second precursor sources 120, 124 into the deposition chamber 102 through first and second precursor delivery lines 110, 114, respectively. The first and second precursor delivery lines 110, 114 include high conductance line portions 130, 134, respectively. A rapid purge (RP) gas can be stored in at least two RP gas sources 128-1, 128-2. The precursor delivery system 106 is configured to deliver the rapid purge (RP) gas from the RP gas sources 128-1, 128-2 into the deposition chamber 102 through respective ones of RP gas delivery lines 118-1, 118-2. The RP gas delivery lines 118-1, 118-2 include high conductance line portions 138-1, 138-2, respectively. A continuous purge (CP) gas can be stored in at least two CP gas sources 134-1, 134-2. The precursor delivery system 106 is configured to deliver the CP gas from the CP gas sources 134-1, 134-2 into the deposition chamber 102 through respective ones of CP gas delivery lines 114-1, 114-2.

The first and second precursors are configured to be delivered from the first and second precursor sources 120, 124, respectively, by independently actuating first and second precursor atomic layer deposition (ALD) valves 140 and 144 that are connected in parallel to the common gas distribution plate 112. Additionally, the RP purge gas is configured to be delivered from the RP purge gas sources 128-1, 128-2 by independently actuating two respective purge gas atomic layer deposition (ALD) valves 148-1, 148-2 that are connected in parallel to the common gas distribution plate 112. The ALD valves 140, 144, 148-1 and 148-2 and the respective delivery lines connected to the gas distribution plate 112 can be arranged to feed the respective gases into the nozzle 108 through a multivalve block assembly 150, which may be attached to a lid of the deposition chamber 102. In the illustrated configuration, the ALD valves 140, 144, 148-1 and 148-2 are final valves before the respective gases are introduced into the deposition chamber 102.

By way of example only, the first and second precursors can include VCl₄ and NH₃, respectively, that are delivered into the deposition chamber 102 from respective VCl₄ and NH₃ sources through respective precursor delivery lines to form, e.g., VN. The precursor delivery system can additionally be configured to deliver Ar as the purge gas into the process chamber from Ar sources through purge gas delivery lines. Purge gases may be delivered as a continuous purge (CP) gas, which may be delivered through precursor ALD valves, and/or as a rapid purge (RP) gas, which may be delivered through dedicated purge gas ALD valves as shown in FIG. 1. The illustrated precursor delivery system 100 can be configured to deliver Ar as an RP gas into the process chamber 102 from the purge gas sources 128-1, 128-2 through respective purge gas delivery lines and purge gas ALD valves 148-1, 148-2.

According to various embodiments, the thin film deposition system 100 is configured for thermal ALD without an aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relative high aspect ratios. Without being limited by theory, one possible reason for this is that a plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

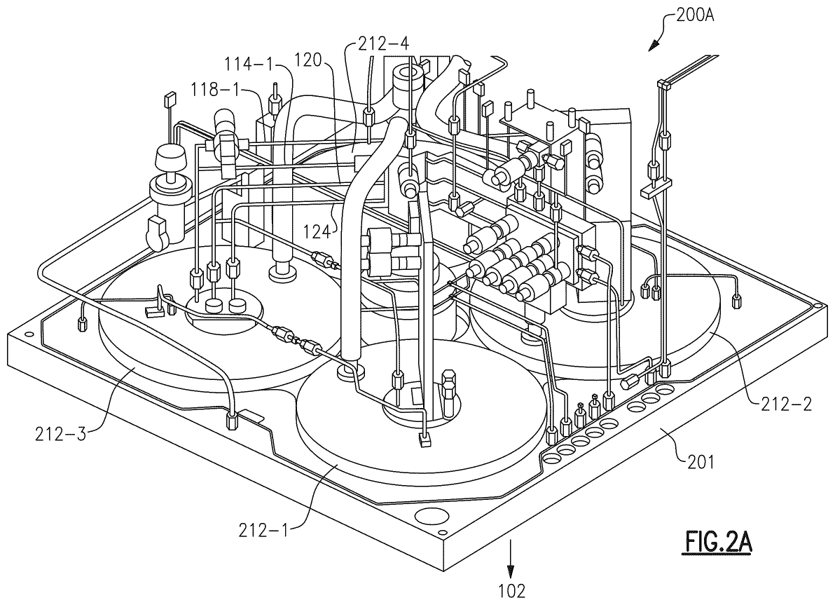

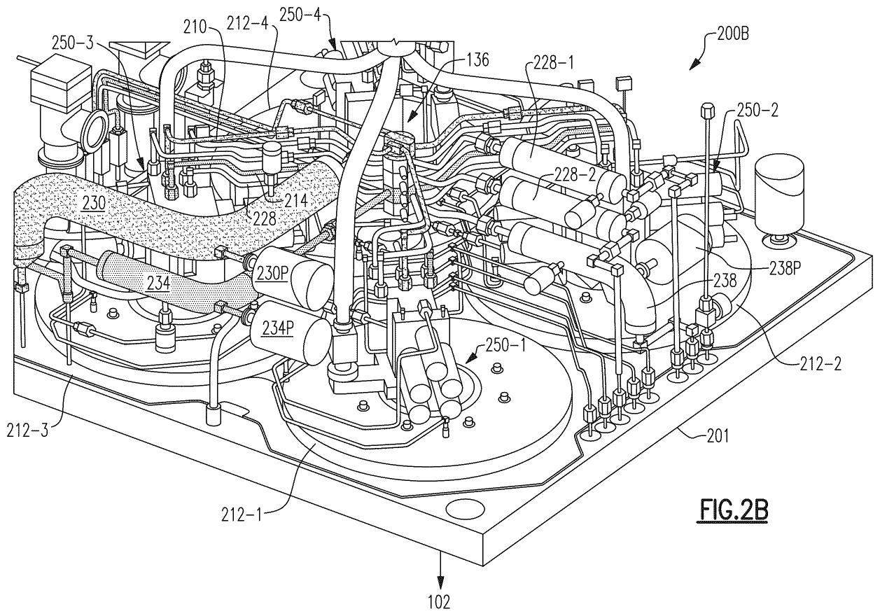

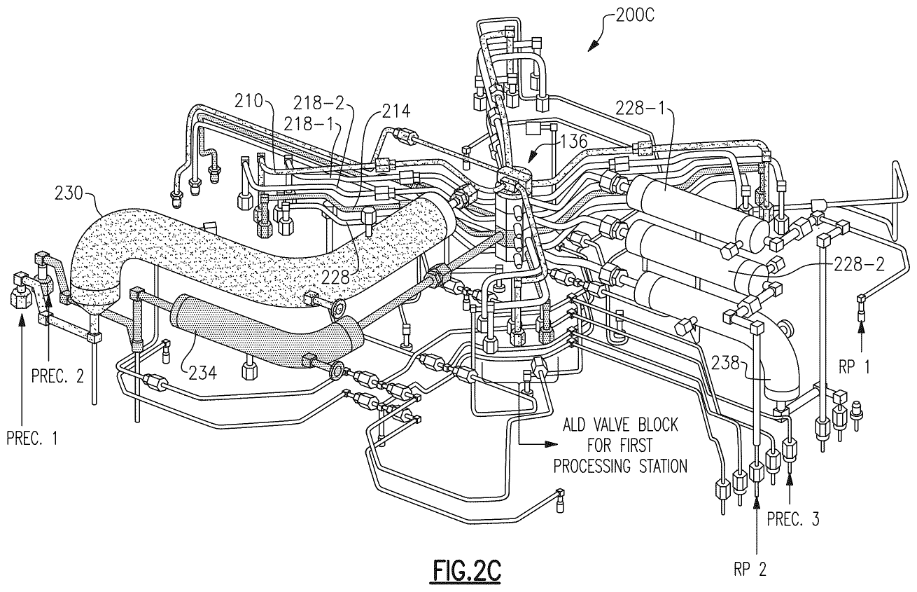

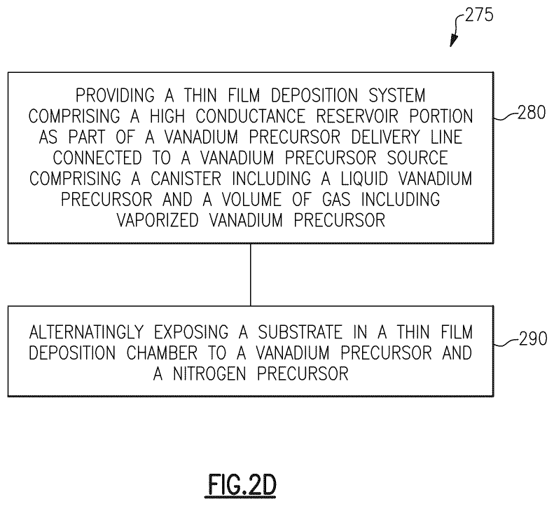

The illustrated precursor delivery system 100 provides increased flow and stability of the precursors delivered into the deposition chamber 102 in part due to the presence of the high conductance line portions of the delivery lines. The inventors have discovered that achieving short precursor exposure times without sacrificing stability can be particularly difficult for process chambers having multiple process stations as described herein (e.g., FIGS. 2A, 2B), due the higher combined volumes of precursors that are delivered to the multiple process stations.

FIG. 2A shows an example base deposition chamber which can particularly benefit from various embodiments disclosed herein, including high conductance line portions and ALD valves. FIG. 2A shows a perspective view of a lid portion 201 of a deposition chamber 200A comprising multiple processing stations. Each processing station is configured to process a substrate under a unique process condition, including a process temperature, a process pressure and a combination of precursors. In the illustrated embodiment, there are four processing stations having corresponding lids 212-1, 212-2, 212-3, 212-4. The processing stations can be, e.g., single substrate processing stations each configured to deliver one or more precursors through respective precursor delivery lines. While the illustrated process chamber is a multi-station process chamber, it will be appreciated that the embodiments disclosed herein are not limited thereto, and can be implemented in any suitable single wafer multi-wafer process chambers. The illustrated top portions of the lids 212-1, 212-2, 212-3, 212-4 are physically outside the deposition chamber 102 (FIG. 1). Inside the process chamber, each of the lids 212-1, 212-2, 212-3, 212-4 includes or has attached thereto a gas distribution plate (not shown), also referred to as a showerhead, configured to diffuse the precursor(s) over a substrate on the susceptor.

Each processing station can be configured, e.g., in a similar manner as described above with respect to FIG. 1, and comprises the respective one of the lids 212-1, 212-2, 212-3, 212-4. Referring back to FIG. 1, after a respective one of the MFCs, each of the gas delivery lines branch off into multiple lines at a respective manifold 136. Each of the branched off lines can feed a respective gas into one of the processing stations. For example, feeding into each lid are four gas lines, e.g., ¼″ lines, which can correspond to gas delivery lines 118-1, 114-1, 110 and 114 as described above with respect to FIG. 1. The illustrated deposition chamber comprises one or more processing stations each configured to process a substrate on a support, e.g., a susceptor, under a process condition, in a similar manner as described above with respect to FIG. 1.

The example base deposition chamber such as that shown in FIG. 2A can particularly benefit from various combination of embodiments disclosed herein, including high conductance line portions and ALD valves, such that exposures to each precursor can be substantially shortened without sacrificing desirable film characteristics such as conformality, step coverage and uniformity.

### High Conductance Reservoir Portions for High-Speed Cyclic Deposition of Vanadium Nitride

Various combinations of enabling features for high-speed cyclic deposition as disclosed herein include high conductance line portions that serve as an intermediate reservoir with high conductance and flow rate therethrough. FIG. 2B shows a perspective view of a lid portion of a deposition chamber comprising multiple processing stations that is configured to introduce precursors through precursor delivery lines having high conductance line portions, according to embodiments. The lid portion 201 of the deposition chamber 200B can represent one example of the lid portion 201 described in FIG. 2A in which various features including high conductance line portions and ALD valves have been implemented, according to various embodiments. For clarity, FIG. 2C shows a perspective view of the precursor delivery lines having high conductance line portions for the process chamber illustrated in FIG. 2B, without other components.

The illustrated lid portion 201 of a deposition chamber 200B includes base components that are similar to those of the lid portion 201 of the deposition chamber 200A described above with respect to FIG. 2A, a detailed description of which is not repeated herein for brevity. For example, the lid portion deposition chamber 200B includes the lids 212-1, 212-2, 212-3, 212-4, each of which is equipped with a precursor delivery system for delivering a plurality of precursors and one or more purge gases. Each of the precursors and purge gases is connected to the deposition chamber 200B by a respective gas delivery line. Each of the delivery lines is connected to the respective gas source on the one end as described above with respect to the thin film deposition system illustrated in FIG. 1. On the other end, the delivery line is split into four local delivery lines connected to ALD valves that are in turn connected to showerheads four processing stations.

In the thin film deposition chamber 200A illustrated in FIG. 2A, the gas delivery lines may be standard gas lines having a diameter, e.g., 0.25-0.5 inches, which can be constant throughout the gas delivery lines. Unlike the gas delivery lines of the thin film deposition chamber illustrated in FIG. 2A, at least some of the gas delivery lines illustrated in FIG. 2B comprise increased conductance line portions serving as intermediate gas reservoirs between the precursor or purge gas sources and the thin film deposition chamber 200B, according to various embodiments.

In reference to FIG. 2B in conjunction with FIG. 2C for clarity, the high conductance line portions are disposed between the respective gas sources and the thin film deposition chambers, prior to the gas delivery lines being splitting into local delivery lines for delivering the gases into multiple processing stations.

Referring to FIGS. 2B and 2C, the illustrated thin film deposition chamber 200B and the precursor delivery system 200C are configured for delivering three different precursors and a rapid purge gas through respective gas delivery lines including high conductance line portions. In a similar manner as described above with respect to FIG. 1, first, second and third precursors (Prec. 1, Prec. 2, Prec. 3) are stored in their respective first, second and third precursor sources (not shown). In a manner similar to the precursor delivery system 106 (FIG. 1) described above, the precursor delivery system 200C is configured to deliver the first, second and third precursors (Prec. 1, Prec. 2, Prec. 3) from the first, second and third precursor sources into the deposition chamber 102 (FIG. 1) through first, second and third precursor delivery lines 210, 214 and 228, respectively. The first, second and third precursor delivery lines 210, 214 and 228 include respective high conductance line portions 230, 234 and 238, respectively. The high conductance line portions 230, 234 and 238 have attached thereto pressure monitoring sensors 230P, 234P and 238P, respectively. In addition, a rapid purge (RP) gas can be stored in respective RP gas sources (not shown). In a manner similar to the precursor delivery system 106 (FIG. 1) described above, the precursor delivery system 200C is configured to deliver the RP gas from the RP gas sources into the deposition chamber 102 (FIG. 1) through respective ones of RP gas delivery lines 218-1, 218-2. The RP gas delivery lines 218-1, 218-2 include high conductance line portions 228-1, 228-2, respectively.

According to various embodiments, the high conductance delivery line portions serving as intermediate gas reservoirs are included as at least portions of some of the gas delivery lines. The inventors have discovered that the relatively high conductance of the high conductance line portions advantageously allows for relatively high volumes of gases to pass therethrough to reduce the precursor or purge gas exposure time. By way of example only, in the example configurations illustrated in FIGS. 2B and 2C, the high conductance line portions 230, 234 and 238 for precursor the delivery lines 210, 214 and 228, respectively, and the high conductance line portions 228-1 and 228-2 for RP purge gas delivery lines 218-1 and 218-3, respectively, are elongated in a flow direction e.g., in a cylindrical shape, and have a diameter exceeding 0.5 in., 1 in., 1.5 in., 2.0 in., 2.5 in., 3.0 in., 3.5 in., 4.0 in., 4.5 in., 5 in., or having a value in a range defined by any of these values. The high conductance line portions additionally have a length exceeding 5 in., 10 in., 20 in., 50 in., 100 in., or a value in range defined by any of these values. As configured, relative to the low conductance line portions being formed of standard diameters, e.g., 0.25″ or 0.5″, the conductance of the high conductance line portions can be greater than 4, 10, 20, 50, 100, 200, 500, 1000, 2000, 5000, 10,000 or a value in a range defined by these values or higher, according to various embodiments.

The inventors have further found that, in addition to high conductance for high flow rate, the high conductance line positions are advantageously configured to supply sufficient volumes of the precursor and purge gases such repeated or relatively long exposures result in relatively small amount of pressure fluctuation or drift. According to various embodiments, the high conductance line portions have a volume exceeding 0.3 L, 0.5 L, 1.0 L, 1.5 L, 2.0 L, 2.5 L, 3.0 L, 3.5 L, 4.0 L, 4.5 L, 5.0 L, of a value in a range defined by any of these values. By way of example only, in the embodiment illustrated in FIGS. 2B and 2C, the high conductance line portions of the gas delivery lines for the Prec. 1 (e.g., VCl₄), the Prec. 2 (e.g., NH₃) and RP (e.g., N₂) have volumes of 3.4 L, 0.56 L and 0.4 L, respectively.

Advantageously, the delivery lines including the high conductance line portions as described herein are configured to deliver high precursor doses for a given pulse of precursor exposure. According to embodiments, the delivery lines are configured to flow gases at flow rates greater than 50 sccm, 1000 sccm, 2000 sccm, 4000 sccm, 6000 sccm, 8000 sccm, 10,000 sccm, for a value in a range defined by any of these values. Advantageously, the relatively high doses can reduce the exposure time or the number of pulses to reach a certain substrate surface saturation level, or both.

The inventors have realized that, in addition to the physical shape and dimensions of the high conductance delivery lines as disclosed herein, the positioning thereof relative to the point of entry into the deposition chamber can be advantageously optimized to reduce the residence time of the precursor. As illustrated in FIG. 2B, the high conductance line portions 230, 234 and 238 for precursor delivery and the high conductance line portions 228-1, 228-2 for purge gas delivery are disposed above the lid portion 201 to overlap at least one of the lids 212-1, 212-2, 212-3, 212-4. The corresponding lids 212-1, 212-2, 212-3, 212-4 have disposed thereunder, respective ones of gas distribution plates 250-1, 250-2, 250-3, 250-4 each configured in a similar manner as shown in FIG. 1. In addition, from the point of exit from the high conductance line portions, the length of low conductance line portions (including the portion from the point of exit to the manifold 136 and the portion from the manifold to the ALD valve block) to the respective ALD block for a given gas is within 30″, 25″, 20″, 15″, 10″ or a distance within a range defined by any of these values.

FIG. 2D is a flow chart illustrating a method of depositing a vanadium nitride thin film using the thin film deposition system including a thin film deposition chamber and a precursor delivery system configured with precursor delivery lines including high conductance line portions, according to embodiments. The method 275 includes providing 280 a thin film deposition system comprising a high conductance reservoir portion as part of a vanadium precursor delivery line connected to a vanadium precursor source comprising a canister including a liquid vanadium precursor and a volume of gas including vaporized vanadium precursor. The method 275 additionally includes alternatingly exposing 290 a substrate in a thin film deposition chamber to a vaporized vanadium precursor and a nitrogen precursor.

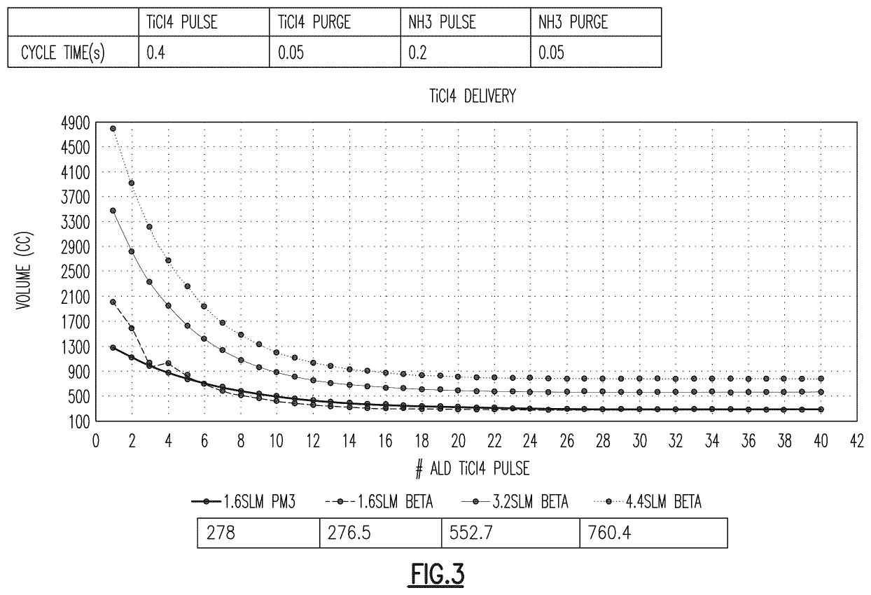

FIG. 3 is an experimental graph showing precursor volumes delivered to a process chamber with successive exposure pulses for different high conductance line portions having different volumes. The measurement was taken from a precursor delivery line similar to the first precursor delivery line 210 including the high conductance line portion 230 as described above with respect to FIGS. 2B and 2C, using TiCl₄ as an example. The measurements were made by first charging the precursor delivery line including the high conductance line portion and successfully applying multiple cycles of ALD deposition. The measurements were taken for delivery lines configured for flow rates of 1.6 standard liters per minute (SLM), 3.2 SLM and 4.4 SLM. The experimental ALD cycle used for obtaining the data is indicated at top, which included a 0.4 sec. TiCl₄ pulse, a 0.05 sec, rapid purge, a 0.2 sec. NH₃ pulse and 0.05 sec. rapid purge carried out in sequence. For the precursor delivery lines configured for different flow rates of 1.6 SLM, 3.2 SLM and 4.4 SLM, the volumes of gas delivered with each successive pulse decreases nonlinearly with increasing number of pulses. For the precursor delivery lines configured for different flow rates of 1.6 SLM, 3.2 SLM and 4.4 SLM, the observed volumes of precursor delivered by the first pulse were about 0.27 L, 0.55 L and 0.76 L, respectively, with the 0.4 sec. pulse. According to various embodiments, volume of gas delivered per 0.4 sec can exceed 0.2 L, 0.4 L, 0.6 L, 0.8 L, 1.0 L, 1.2 L, 1.5 L, or have a value in a range defined by any of these values.

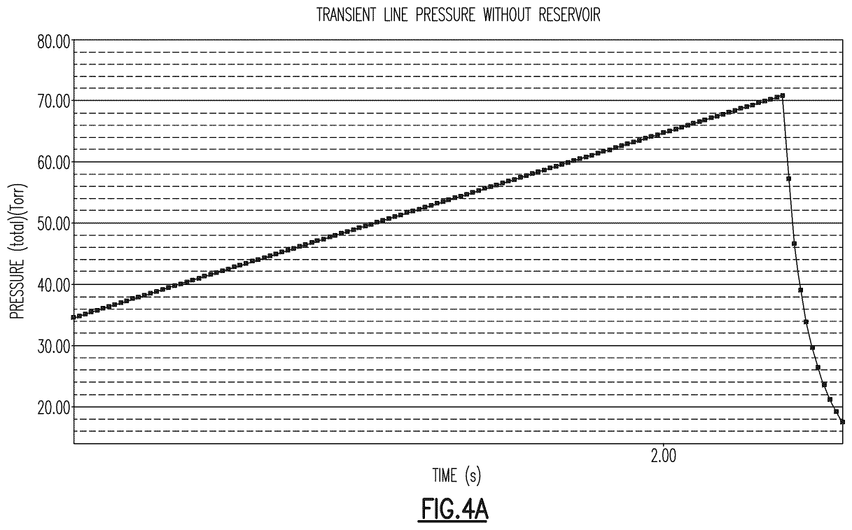

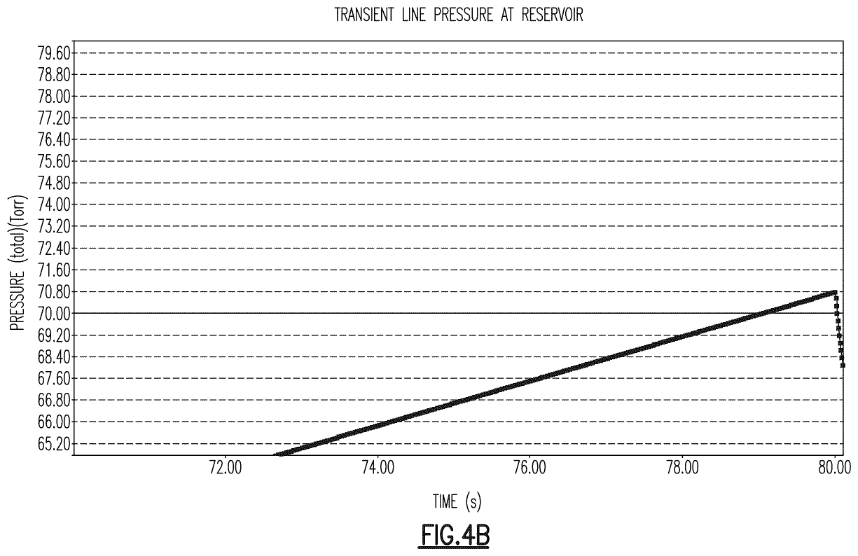

FIGS. 4A and 4B show experimental measurements of pressure changes in the precursor delivery lines, with and without a high conductance line portion, respectively, upon opening an atomic layer deposition (ALD) valve to introduce the precursor into the thin film process chamber. The pressure change was measured from a precursor delivery line similar to the first precursor delivery line 210 including the high conductance line portion 230 respectively as described above with respect to FIGS. 2B and 2C, using the pressure monitoring sensor 230P as shown in FIG. 2B. The measurements were made by first charging the precursor delivery line 210 with TiCl₄ as an example precursor and opening the ALD valve connected thereto for 0.1 sec. As shown, the presence of the high conductance line portion 230 advantageously greatly reduces the pressure drop in the precursor delivery line. As shown in FIG. 4A, without the high conductance line portion 230, the pressure drop inside the precursor delivery line can exceed 50 Torr or 70% (from 71 Torr to 17 Torr). In contrast, opening a valve, e.g., an ALD valve connected to the precursor delivery line 210 including the high conductance line portion 230 according to embodiments to introduce a precursor into the thin film deposition chamber results in a significantly lower pressure drop. As shown in FIG. 4B, the pressure drop inside the precursor delivery line does not exceed 3 Torr or 5%. As described infra with respect to FIG. 4A, the inventors have shown that the pre-charge pressure can be critical for obtaining high step coverage values for films deposited in a via or trench.

Based on experiments similar to that illustrated in FIGS. 4A and 4B, the inventors have determined that one or more of a pressure inside the high conductance line portion immediately before actuating the ALD valve, a pressure change in the high conductance line portion during exposure, a run-to-run standard deviation of the mean pressure inside the high conductance line portion, and a run-to-run pressure drift of the mean pressure inside the high conductance line portion can be critical for certain film characteristics, such as step coverage. According to embodiments, the pressure inside the delivery line portion prior to opening the ALD valve to expose the substrates is kept above 40 Torr, 50 Torr, 60 Torr, 70 Torr, 80 Torr, 100 Torr, 120 Torr, 140 Torr, 160 Torr, 180 Torr, 200 Torr, or a value in a range defined by any of these values. According to embodiments, at least in part due to the presence of the high conductance line portions, a pressure change or drop at the high conductance line portion upon valve opening, e.g., for less than 1 sec., is less than 50 Torr, 40 Torr, 30 Torr, 20 Torr, 10 Torr, 5 Torr, 3 Torr, 1 Torr, or a value in a range defined by any of these values, or less than 70%, 60%, 50%, 40%, 30%, 20%, 10%, 5%, 2%, or a value in a range defined by any of these values. Further according to embodiments, at least in part due to the presence of the high conductance line portions, a run-to-run standard deviation of pressure change at the high conductance line portion is less than 5 Torr, 4 Torr, 3 Torr, 2 Torr, 1 Torr, 0.5 Torr, 0.3 Torr, 0.1 Torr, or a value in a range defined by any of these values, or less than 20%, 15%, 10%, 5%, 2%, 1% of the mean value, or a value in a range defined by any of these values. Further according to embodiments, at least in part due to the presence of the high conductance line portions, a run-to-run drift of the mean pressure at the high conductance line portion is less than 20 Torr, 15 Torr, 10 Torr, 8 Torr, 6 Torr, 4 Torr, 2 Torr or a value in a range defined by any of these values, or less than 30%, 25%, 20%, 15%, 10%, 5% of the mean value, or a value in a range defined by any of these values. Without limitation, further experimental validation of these parameters in providing various process stability and improved film characteristics including step coverage for high aspect ratio openings and within-wafer uniformity of the thickness is described elsewhere in the application.

Advantageously, the high conductance line portions serving as intermediate gas reservoirs according to embodiments allow for various advantageous technical effects described herein, e.g., high flow rate and reduced exposure time for process chambers including one or more processing stations, without excessively increasing the pressure inside the precursor delivery line, which can in turn improve safety in accordance with the industry standard. According to embodiments, the increased conductance line portion is configured to maintain a pressure inside the delivery lines that is less than 650 Torr, 600 Torr, 550 Torr, 500 Torr, 450 Torr, 400 Torr, 350 Torr, 300 Torr, 250 Torr, 200 Torr, 150 Torr, 100 Torr, 50 Torr, or a value in a range defined by any of these values.

Vanadium Precursor Delivery System Configured with Pre-Conditioning System

The inventors have discovered that some vanadium precursors, e.g., VCl₄, can partially decompose while stored in a canister. Without being bound to any theory, inventors have discovered that VCl₄ can decompose according to the following reaction:

VCl₄(l)→VCl₃(s)+½Cl₂(g)

As such, over time, a mixture of gases containing vaporized VCl₄ that is extracted from the vanadium precursor source can have substantial amounts of Cl₂ (g). The decomposition and the resulting byproducts can pose a significant challenge for reliable and repeatable deposition. In particular, the inventors have discovered that, when the amount of Cl₂ in the mixture of gases extracted from the precursor source exceeds a threshold amount, deposition may not occur, or may occur after a significant delay. Furthermore, when the amount of Cl₂ in the mixture of gases extracted from the precursor source is too high, an underlying substrate material can be etched by the Cl₂ gas, much less allowing for commencement of deposition of vanadium nitride. Without being bound to any theory, such lack of or delayed deposition may occur due to Cl₂ (g) serving as an etchant that competes with deposition of VN. To address these and other effects arising from transient precursor effects, inventive aspects of the present disclosure include providing a vanadium precursor delivery system configured with a conditioning sub-system.

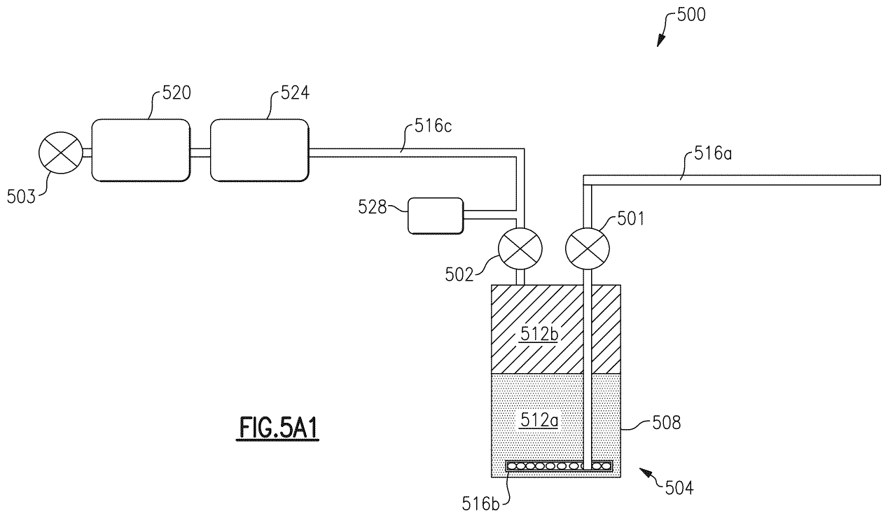

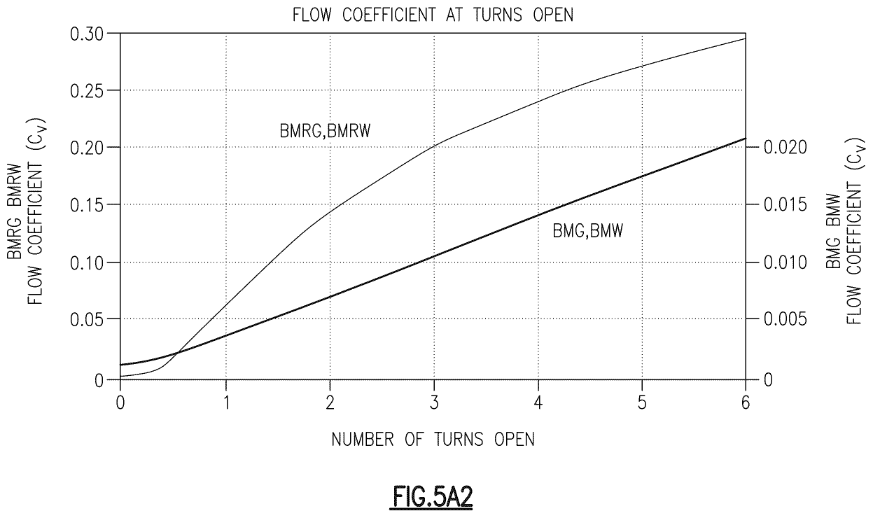

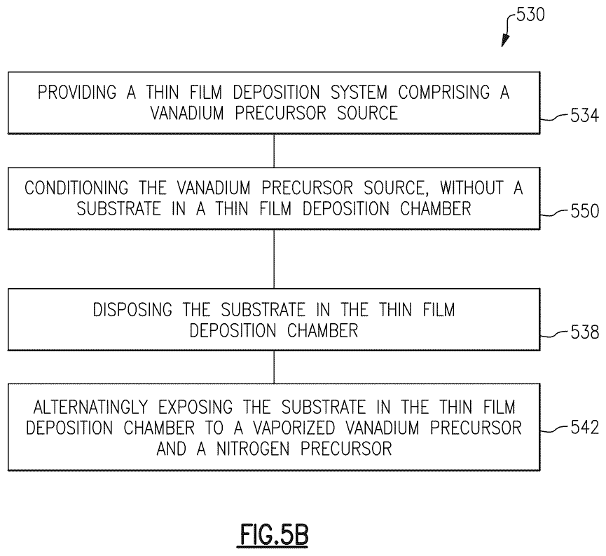

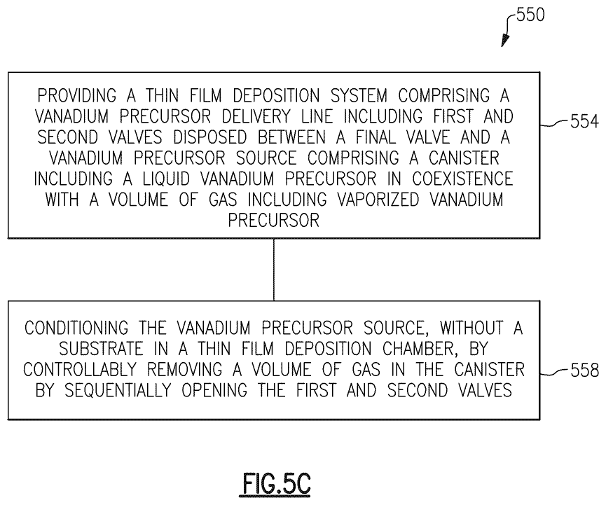

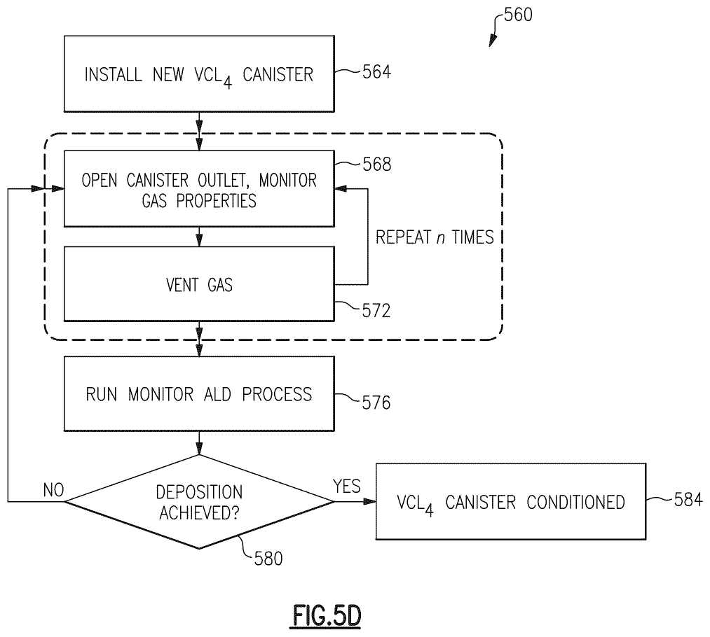

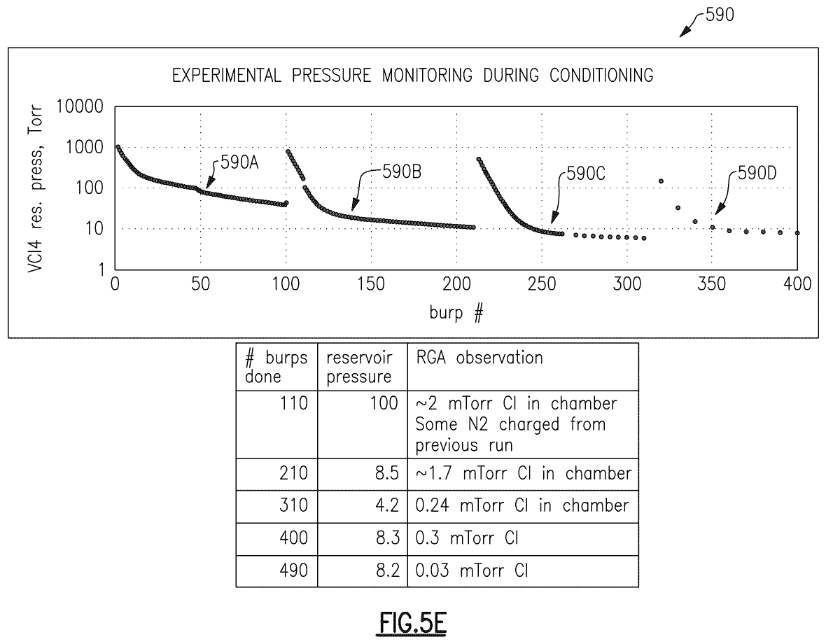

FIG. 5A1 illustrates a liquid precursor delivery system for delivering a vaporized vanadium precursor into a thin film deposition chamber, e.g., the thin film deposition chamber described above with respect to FIG. 1, according to embodiments. The liquid precursor delivery system 500 includes a conditioning sub-system to alleviate transient effects associated with some vanadium liquid precursors, e.g., effects associated with decomposition of the liquid precursor as described above. The liquid precursor delivery system 500 includes a liquid precursor source unit 504. The liquid precursor source unit 504 includes a canister 508 having stored therein a liquid precursor 512a. A push gas line 516a is connected to the canister 508 and is connected to a bubbler 516b. The push gas line 516a is connected to a carrier gas source, e.g., a N₂ source, for delivering the carrier gas as input into the canister 508. A precursor delivery gas line 516c is connected to the liquid precursor source unit 504 and configured to deliver a gas mixture 512b as output to the deposition chamber.

In operation, to deliver the liquid precursor 512a out of the liquid precursor source unit 504, a push gas inlet valve 501 is opened and a push gas, e.g., hydrogen or an inert gas such as helium, argon or nitrogen is supplied through the push gas line 516a to the canister 508, in order to bubble the push gas through the bubbler 516b. Upon bubbling the inert gas through the bubbler 516b, a gas mixture 512b is formed to coexist with the liquid precursor 512a. The liquid precursor may include vaporized vanadium precursor, the carrier gas and any byproduct resulting from instabilities of the vanadium precursor. For example, without being bound to any theory, the gas mixture 512b can include Cl₂ (g). The gas mixture 512b is pushed out of the canister 508 and delivered to the thin film deposition chamber when first and second precursor outlet valves 502, 503 are open.

While not shown for clarity, one or more heaters may be disposed at various locations of the liquid precursor source unit 504 to heat the canister 508 and/or the path including the push gas line 516a, the bubbler 516b and the precursor delivery line 516c to regulate the temperature at various points in the delivery path of the vanadium precursor.

The temperature of the liquid precursor 512a may be controlled, e.g., from room temperature up to a boiling point of the liquid precursor, e.g., the vanadium precursor. For example, for VCl₄ having a boiling temperature of about 148-154° C., the temperature at any of the above points in the delivery path may be controlled to be higher than 20° C., e.g., higher than 40° C., 60° C., 80° C., 100° C., 120° C., 140° C., 150° C., or a temperature in a range defined by any of these values. The inventors have found that heating VCl₄ to any of these temperatures above room temperature can greatly enhance step coverage, as described elsewhere in the application. However, embodiments are not so limited and in other embodiments, temperature at any of the above points in the delivery path may be controlled to be lower than 20° C. e.g., 0-20° C.

Still referring to FIG. 5A1, the liquid precursor delivery system 500 includes the conditioning subsystem for conditioning the liquid precursor that is controlled by a plurality of valves. The conditioning subsystem can be used to controllably remove a portion of the volume of the gas mixture 512b in the canister 508. Controllably removing the gas mixture 512b can advantageously remove decomposition byproducts such as Cl₂ (g). The push gas inlet valve 501 controls the inflow of the push gas from the push gas line 516a into the canister 508 through the bubbler 516b. The first precursor outlet valve 502 controls the outflow of the gas mixture 512b from the canister 508. The second precursor outlet valve 503 controls the flow of the gas mixture 512b into the thin film deposition chamber. These valves can controllably remove a portion of the gas mixture 512b in the canister 508 by sequentially opening the first and second precursor outlet valves 502, 503, as described further below.

The conditioning subsystem can additionally include various flow controls and monitors. In the illustrated embodiment, the conditioning system includes a flow controller 520, a concentration monitor 524 and a pressure gauge 528 disposed between the first and second precursor outlet valves 502, 503. The flow controller 520 can be a suitable flow controller such as a metering valve or a mass flow controller. The concentration monitor 524 can be a suitable monitor such as a residual gas analyzer or a mass spectrometer. The concentration monitor 524 can also monitor the concentration of Cl₂ and VCl₄. The pressure gauge 528 can be a suitable gauge such as a pressure transducer. It will be appreciated that the relative positions of these components can be altered. For example, the flow controller 520 may be disposed closer to the canister 508, e.g., between the pressure gauge 528 and the first precursor outlet valve 502.

The linear-type curve in FIG. 5A2 illustrates the flow coefficient of one example metering valve that can be used to control the flow of the vaporized vanadium precursor. The inventors have found that, when the flow of the vaporized vanadium precursor is limited by the metering valve, the flow coefficient can be critical for obtaining high step coverage. The x-axis shows the number of turns, where 0.4 “turns open” correspond to an opening size of 10 mils and 2 “turns open” correspond to an opening size of 50 mils. In turn, 10 mils correspond to a Cᵥ of about 0.002 and 50 mils correspond to a Cᵥ of about 0.008. As discussed elsewhere, the inventors have found that, for high step coverage, the Cᵥ should be greater than 0.002, e.g., greater than 0.004, 0.006, 0.008, 0.010, 0.012, 0.014, 0,016, 0.018, 0,020, or a value in a range defined by any of these values.

Referring to the illustrated conditioning subsystem in FIG. 5A1 in conjunction with FIG. 1, in some embodiments, the first precursor source 120 (FIG. 1) may correspond to the liquid precursor source unit 504. Under this arrangement, the second precursor outlet valve 503 (FIG. 5A1) may correspond to the ALD valve 140 (FIG. 1), and the volume between the first and second precursor outlet valves 502, 503 (FIG. 5A1) may include the high conductance reservoir portion 130 (FIG. 1). The pressure gauge 528 (FIG. 5A1) may correspond to the pressure gauge P (FIG. 1) and the flow controller 520 may correspond to the mass flow controller 132 (FIG. 1). However, embodiments are not so limited and in other arrangements, the illustrated conditioning subsystem in FIG. 5A1 may be in addition to, e.g., precede, the high conductance reservoir portion 130.

FIG. 5B is a flow chart illustrating a method of depositing a vanadium nitride thin film including precursor conditioning. The method 530 comprises providing 534 a thin film deposition system comprising a vanadium precursor source. The method additionally comprises conditioning 550 the vanadium precursor source, without a substrate in a thin film deposition chamber. The method further comprises disposing 538 the substrate in the thin film deposition chamber and alternatingly exposing 542 the substrate in the thin film deposition chamber to a vaporized vanadium precursor and a nitrogen precursor.

FIG. 5C is a flow chart illustrating method of conditioning 550 a vanadium precursor source, according to embodiments. The method of conditioning 550 comprises providing 554 a thin film deposition system comprising a vanadium precursor delivery line. The thin film deposition system can be similar to those described above according to FIGS. 1-3 including a thin film deposition chamber and a precursor delivery system configured with precursor delivery lines including high conductance reservoir portions. The vanadium precursor delivery line includes the first and second outlet valves 502, 503 (FIG. 5A1) disposed between a final valve and the vanadium precursor source unit 504 comprising the canister 508 including a liquid vanadium precursor 512a in coexistence with a volume of gas mixture 512b including vaporized vanadium precursor. The vanadium precursor delivery system can be in accordance with the liquid precursor delivery system 500 described above with respect to FIG. 5A1. The final valve can be, e.g., an ALD valve as described above with respect to FIGS. 1-3.

The method of conditioning 550 additionally comprises conditioning 558 the vanadium precursor source, without a substrate in the thin film deposition chamber, by controllably removing a volume of gas in the canister 508 by sequentially opening the first and second outlet valves 502, 503 (FIG. 5A1). Referring back to FIG. 5A1, conditioning comprises first opening the first precursor outlet valve 502 while keeping the second precursor outlet valve 503 closed, thereby equilibrating the pressure in the volume between the first and second precursor outlet valves 502, 503 with the gas mixture 512b in the canister 508, followed by closing the first precursor outlet valve 502 to enclose the volume of gas mixture between the first and second precursor outlet valves 502, 503. Thereafter, the second precursor outlet valve 503 is opened while keeping the first precursor outlet valve 502 closed to pump out the gas mixture. This controlled removal of a limited volume of the gas mixture may be repeated a plurality of times. The inventors have discovered that the controlled removal of the volume of gas in this manner preferentially removes unwanted byproducts of decomposition of the liquid precursor 512a. For example, after Cl₂ produced by decomposition of VCl₄ that is dissolved in the liquid precursor 512a reaches an equilibrium saturation concentration, the excess Cl₂ volatilizes into the gas mixture 512b above the liquid precursor 512a. Once the gas mixture 512b containing the volatilized Cl₂ is pumped out by sequentially opening and closing the first and second precursor outlet valves 502, 503 as described above, the controlled removal process can be repeated. Thus, according to embodiments, the method of conditioning 550 additionally comprises conditioning the vanadium precursor source, without a substrate in a thin film deposition chamber, by controllably removing a portion of the volume of gas in a plurality of steps, wherein each step removes a sub-portion of the portion of the gas mixture 512b in the canister 508 (FIG. 5A1). Advantageously, by repeated controlled removal in this manner, the concentration of Cl₂ from the gas mixture 512b can be reduced.

The inventors have discovered that substantial decomposition of vanadium liquid precursor can occur in the canister 508 even at room temperature. For example, the canister 508 as purchased and installed may contain a substantial amount of Cl₂. Thus, according to embodiments, the method of conditioning 550 can include controllably removing a volume of gas over the vanadium precursor liquid form in a canister that has been just installed, or after an installed canister has not been used for a period of time, e.g., greater than several hours, greater than a day, greater than a week, greater than a month, or a period of time in a range defined by any of these durations.

FIG. 5D illustrates a conditioning method using the conditioning system of the liquid precursor delivery system 500, according to embodiments. The method 560 includes, after installing 564 a canister, opening 568 the canister outlet to monitor gas properties, and venting 572 the canister. Opening 568 and venting 572 the canister processes are similar to the controlled removal process described above with respect to FIG. 5C. The process may be repeated n number of times until a predetermined condition is observed from monitoring. The method 560 additionally includes running 576 a monitor ALD process and determining 580 whether or not deposition is achieved. Upon determining that deposition is achieved, the canister (e.g., VCl₄) can be considered to have been conditioned 584.

Monitoring the gas properties includes monitoring one or both of a pressure and a concentration within, e.g., the volume of gas between the first and second precursor outlet valves 502, 503, which can include a high conductance reservoir portion, such as the high conductance line portion 130 in the system illustrated in FIG. 1.

As described above, when the amount of Cl₂ in the mixture of gases extracted from the precursor source is too high, an underlying substrate material can be etched by the Cl₂ gas, much less allowing for deposition of vanadium nitride. The inventors have discovered that controllably removing the volume of gas from the canister 508 as described above until a predetermined target pressure or gas mixture composition is reached can be effective as an indicator to initiate the deposition.

FIG. 5E illustrates an example of experimental monitoring during conditioning of a vanadium precursor source to determine if the liquid precursor source is ready for deposition, according to embodiments. The illustrated graph 590 shows on the y axis, the pressure measured by the pressure gauge 528 (FIG. 5A1) as a function of number of controlled gas removal (also referred to herein as “burping”) of the gas mixture from the volume between the first and second precursor outlet valves 502, 503 (e.g., the volume of high conductance reservoir portion). The illustrated graph 590 shows first to fourth series 590A, 590B, 590C, 590D of controlled removal of the gas over the vanadium precursor after pressurizing the high conductance reservoir portion. Each arrow marks an end of a series of controlled gas removal. Each of the first to fourth series 590A, 590B, 590C, 590D represents the pressure measured using a pressure gauge 528 (FIG. 5A1), which can represent the pressure inside the high conductance reservoir portion 130 (FIG. 1). For each series, the high conductance reservoir portion 130 (FIG. 1) is initially charged to a pressure of about 1000 Torr. Thereafter, a series of controlled gas removal or “burps” is performed from the canister 508 in a manner described above. After each series, a monitor process has been performed, as illustrated in FIG. 5D. The graph shows that, in the first and second series 590A, 590B, the pressure measured before running a monitor process was greater than a predetermined value, e.g., about 10 Torr, and no deposition was observed. In the third and fourth series 590C, 590D, the pressure measured before running a monitor process is less than the predetermined value, and at least partial deposition was observed. Thus, the measured pressure within the volume gas between the first and second precursor outlet valves 502, 503 (FIG. 5A1), which can be the volume of gas in the high conductance reservoir portion, can be used as a conditioning criterion to initiate deposition of vanadium nitride.

According to embodiments, controllably removing the volume of gas mixture can include, after controllably removing a portion of the gas mixture in a plurality of steps, detecting the predetermined pressure to be less than 50%, 20%, 10%, 5%, 2%, 1% or a value in a range defined by any of these values relative to the initial pressure prior to the first controlled removal. In the illustrated experimental graph 590, the pressure was detected to have been reduced from an initial pressure of 1000 Torr to less than 10 Torr, which is less than 1% of the initial pressure.

The inventors have discovered that parameters other than a pressure can be measured as an effective indication of the readiness of the liquid precursor for deposition. For example, as described, when the vanadium precursor comprises VCl₄, the concentration of one or both of VCl₄ and Cl₂ can be measured between the first and second precursor outlet valves 502, 503 using the concentration monitor 524 illustrated in FIG. 5A1. The concentration can be measured using the concentration monitor 524, in a similar manner as the pressure measurements shown in FIG. 5E, e.g., as a function of number of controlled gas removal (or “burps”). According to embodiments, controllably removing the volume of gas mixture can include detecting the predetermined target concentration of one or both of VCl₄ and Cl₂. For example, the predetermined target concentration of Cl₂ can be less than 50%, 20%, 10%, 5%, 2%, 1% or a value in a range defined by any of these values relative to the concentration prior to the first controlled removal.

It will be appreciated that, while the concentration of Cl₂ can be measured effectively from an enclosed volume of gas between the first and second outlet valves 502, 503 that are closed, embodiments are not so limited. In other embodiments, monitoring can be performed without actuating the first and second outlet valves 502, 503. For example, the gas flowing between the canister and the thin film deposition chamber can be continuously monitored without interrupting the flow, e.g., real time. In yet other embodiments, monitoring can be performed farther away from the canister, e.g., anywhere after the canister including the thin film deposition chamber itself. For example, instead of measuring the concentration of Cl₂ at the concentration monitor 524 (FIG. 5A1), a partial pressure of Cl₂ in the thin film deposition chamber can be used as an indication. The table at a lower half of FIG. 5E shows the partial pressure of Cl₂ measured in the thin film deposition chamber using a residual gas analyzer near the end of each of the first to fourth series 590A, 590B, 590C, 590D shown in the illustrated graph 590. As shown, deposition was observed to commence after the measured Cl₂ partial pressure was less than 1.7 mTorr. Thus, according to embodiments, a partial pressure of Cl₂ in the thin film deposition chamber resulting from a decomposition of the liquid vanadium precursor is less than 1 mTorr, e.g., less than 0.8 mTorr, 0.6 mTorr, 0.4 mTorr, 0.2 mTorr, 0.1 mTorr, 0.05 mTorr, or a value in a range defined by any of these values, prior to commencing deposition.

Conformal VN Thin Film Deposition with High Step Coverage Using High Speed Cyclic Deposition

By providing the high conductance line portion serving as intermediate precursor reservoirs in the precursor delivery lines as disclosed herein, the precursor delivery system according to embodiments advantageously improves the speed and stability of the precursors delivered into the process chamber. The increased dosage and stability of the precursors delivered advantageously enables various advantageous methods of depositing a thin film. According to various embodiments, a method of depositing a thin film comprises alternatingly exposing a substrate in a thin film deposition chamber to a plurality of precursors. Exposing the substrate comprises introducing one of the precursors into the thin film deposition chamber through precursor delivery lines each configured to supply the one of the precursors. Alternatingly exposing the substrate comprises pressurizing the high conductance line portion to a first pressure with the first one of the precursors with the final valve, e.g., an ALD valve closed. Subsequently, the final valve is opened for a duration such that the pressure in the high conductance line portion drops by a relatively small amount compared to conventional systems. For example, the pressure in the high conductance line portion remains above a second pressure lower than the first pressure by less than 10% or any other value disclosed above with respect to FIG. 4B. As described above, in carrying out the method, the inventors have determined that one or more of a pressure inside the high conductance line portion immediately before actuating the ALD valve, a pressure change in the high conductance line portion during exposure, a run-to-run standard deviation of the mean pressure inside the high conductance line portion, and a run-to-run pressure drift of the mean pressure inside the high conductance line portion can be critical for certain film characteristics, such as step coverage.

FIG. 6 illustrates, by way of example only, an example precursor delivery sequence for delivering one or more precursors using the precursor delivery system, according to some embodiments. A first and second precursor inlets are connected to first and second precursor delivery lines including high conductance line portions arranged as described above. An ALD cycle comprises a first subcycle for exposing a substrate to the first precursor, and a second subcycle for exposing the substrate to the second precursor. As described above, each of the precursor ALD valves is a three-port valve, and in some implementations, a continuous purge (CP) gas, e.g., an inert gas, may be flown through the ALD valves while the substrate is exposed to the first precursor and/or the second precursor. In the illustrated embodiment, each of the first and second subcycles further comprises a rapid purge (RP) by an inert gas following the exposure to one or both of the first and second precursors, respectively. The rapid purge may be performed using a purge ALD valve as describe above. The rapid purge is higher in magnitude than the continuous purge.

Advantageously, one or both of the first and second precursors may be introduced into the thin film deposition chamber through respective ones of the precursor delivery lines including increased conductance line portions and ALD valves, as described above. Advantageously, an exposure time to reach a saturation level can be substantially reduced for one or both of the first and second precursors. For example, according to some embodiments, for a given precursor, relative to an exposure time to reach a saturation level using conventional gas delivery lines, the exposure time can be reduced by more than 20%, 40%, 60%, 80%, or a value in a ranged defined by any of these values. The surface saturation level can be inferred, e.g., based on deposition rate. That is, relative to an ALD process using a conventional precursor delivery line for a given precursor, substantially the same thickness can be achieved while reducing the exposure time for the precursor by more than 20%, 40%, 50%, 60%, 80%, or a value in a ranged defined by any of these values.

According to embodiments, the exposure time of one or both of the first and second precursors can be less than 1.0 sec., 0.8 sec., 0.6 sec, 0.4 sec, 0.2 sec., 0.1 sec., 0.05 sec., 0.01 sec. or a value in a ranged defined by any of these values. The thin film deposition system is configured to introduce one or both of the first and second precursors through the precursor delivery lines according to embodiments at flow rates such that a surface of the substrate substantially reaches a saturation level, e.g., a saturation level greater than 40%, 60%, 80% or a value in a range defined by any of these values, within the exposure time. In embodiments where a rapid purge follows an exposure to a precursor, durations of one or both of the first and second subcycles can be less than 1.0 sec., 0.8 sec., 0.6 sec, 0.4 sec, 0.2 sec., 0.1 sec., 0.05 sec., 0.01 sec., or a value in a ranged defined by any of these values. By reducing the exposure times of one or both of the first and second precursors, the durations of one or both of the corresponding first and second subcycles may be reduced, thereby reducing the overall ALD cycle time. According to embodiments, a duration of an overall ALD cycle is less than 2.0 sec., 1.5 sec, 1.0 sec., 0.85 sec., 0.5 sec., or a value in a range defined by any of these values.

FIG. 6 illustrates, by way of example only, one specific example precursor delivery sequence for delivering precursors for cyclic deposition or ALD of VN using VCl₄ and NH₃. The illustrated upper exposure cycle can correspond to the exposure cycles that can be implemented using high conductance line portions and ALD valves described herein, and can represent a VCl₄ exposure cycle through first precursor ALD valve 140 (FIG. 1). Similarly, the illustrated lower exposure cycle can correspond to a NH₃ exposure cycle through second precursor ALD valve 144 (FIG. 1). A process station similar to that described above with respect to FIG. 1 or 2B can be employed. Each of the precursor ALD valves 140, 144 (FIG. 1) are also configured to continuously flow a continuous purge (CP) gas, e.g., an inert gas, therethrough. The process station may also be configured to deliver a rapid purge (RP) gas, e.g., an inert gas, through two purge gas ALD valves 148-1, 148-2. The illustration shows typical parameters for a given processing station and flow conditions for different ALD valves.

The inventors have discovered that, when a substrate has a relatively high surface area, e.g., arising from a relatively high area density of high aspect ratio structures, coating the exposed surface with a thin film using ALD process recipes developed based on characterization of thin films formed on a planar or unpatterned substrate or a substrate with relatively low surface area or low area density of high aspect ratio structures may yield thin films having different characteristics at different parts of the exposed surface. For example, the conformality or step coverage as described above may be significantly worse in high aspect ratio structures in substrates having a relatively high area density thereof. Other characteristics that may also be different at different parts of the exposed surface include film stoichiometry, surface roughness, electrical resistivity and film density, to name a few. Without being bound to any theory, one reason for the low uniformity of the characteristics may be the significantly increased exposed surface area of the substrate relative to a planar substrate. Because of the increased exposed surface area, different parts of the exposed surface may receive different magnitudes of the flux of precursors, such that different amounts of precursors may be adsorbed on different parts of the exposed surface. By way of a simplified example only, when a 300 mm semiconductor substrate has formed thereon hundreds of dies each having of the order of 1×10¹⁰ or more transistors and each transistor has one or more vias having a diameter of 10-100 nm and an aspect ratio of 1 to 100, the surface area exposed to precursors during the deposition of the thin film can exceed the surface area of a corresponding unpatterned substrate by 10, 100, 1000 times or more. In addition, local deposition conditions at different parts of the exposed surface may be different. For example, local pressure inside a deep trench or a via may be different, e.g., lower, compared to regions outside the deep trench or the via. In addition, under vacuum conditions, because gas molecules undergo more collisions with sidewalls of the trench or the via, upper portions of the deep trench or the via may adsorb a higher amount of precursor molecules from being subjected to a higher flux.

According to various embodiments described herein, by utilizing higher deposition pressure, among other things, the inventors have discovered that the deposition methods described herein are particularly advantageous for forming thin films comprising VN at different parts of the exposed surface with higher uniformity with respect to various physical characteristics including conformality, step coverage, film stoichiometry, surface roughness, electrical resistivity and film density, to name a few. Thus, the thin film comprising VN formed according to deposition methods disclosed herein have higher uniformity at both local (e.g., within a trench or via) and global (e.g., within-wafer) levels with respect to one or more of these physical characteristics. Thus, the deposition methods according to embodiments are particularly advantageous for forming the thin film comprising VN on a substrate that comprises a surface topography such that a ratio of a surface area of the semiconductor substrate exposed to the one or more vapor deposition cycles to a surface area of a corresponding unpatterned semiconductor substrate exceeds 2, 5, 10, 20, 50, 100, 200, 500, 1000 or has a ratio in a range defined by any of these values, or higher.

Alternatively or additionally, the deposition methods according to embodiments are additionally particularly advantageous for forming the thin film on a substrate that comprises high aspect ratio structures having an opening width less than 1 micron, 500 nm, 200 nm, 100 nm, 50 nm, 20 nm or a value in a range defined by any of these values, an aspect ratio exceeding 5, 10, 20, 50, 100, 200 or a value in a range defined by any of these values, and an area density such that the surface area is greater than a that of a planar substrate as described above. Substrates having such topography may be conformally coated with thin films comprising VN according to embodiments with a step coverage as defined above that exceeds 50%, 60%, 70%, 80%, 90%, 95%, or has a value in a range defined by any of these values or higher. As discussed above, the inventors have found that process conditions for conformally coating a substrate having a relatively high area density of high aspect ratio structures may be optimized according to embodiments to achieve these results. The inventors have discovered that these results may be achieved by controlling, among other things, the reaction chamber pressure or partial pressures of precursors during exposures of the substrate, the deposition rate, the temperature or pressure of precursors being introduced into the reaction chamber, the flow rate of the precursors and the exposure time, to name a few.

The inventors have discovered that relatively higher total or partial pressures achieved using simultaneous activation of two or more precursor ALD valves can lead to improvement in conformality and step coverage when coating a substrate having a relatively high area density of high aspect ratio structures, according to embodiments. Without being bound to any theory, such improvement may be associated with, among other things, lessening the effect of locally reduced partial pressure of precursors inside the high aspect ratio vias or trenches. According to embodiments, total or partial pressures of any of the individual precursors during exposing the substrate during a given subcycle (e.g., V precursor and/or N precursor), may be 1.0-3.0 torr, 3.0-5.0 torr, 5.0-7.0 torr, 7.0-9.0 torr, 9.0-11.0 torr, 11.0-13.0 torr, 13.0-15.0 torr, or a pressure in range defined by any of these values. In each of the exposures to the V precursor and the N precursor, the respective precursor can make up 1-2%, 2-5%, 5-10%, 10-20%, 20-50%, 50-100% of the total amount of gas molecules in the reaction chamber, or a percentage in a range defined by any of these values. The inventors have discovered that, under some circumstances, when the total or partial pressure is outside of these values, step coverage may start to degrade, among other things.

The inventors have discovered that, in part to enable relatively high throughput while delivering relatively high amounts of precursors to the reaction chamber for deposition at relatively high total or partial pressures, the flow rates of the precursors into the reaction chamber should be significantly higher than those used in process conditions for forming thin films on planar substrates and/or substrates with low (e.g., <1) aspect ratio structures. The high flow rates can in turn may be achieved by increasing one or both of the temperatures or the pressures of the precursors prior to introduction into the reaction chamber. For example, for precursor in liquid form under manufacturing conditions, the liquid precursors or the canisters may be heated to temperatures higher than a room temperature, e.g., 30-60° C., 60-80° C., 80-100° C., 100-120° C., 120-150° C., or a temperature in a range defined by any of these values, to increase the vapor generation rate. The lower and upper bottle temperatures of these ranges may be determined in part based on the vapor pressure of the precursor and the decomposition temperature of the precursor, respectively. By way of example, VCl₄ may be heated to about 20-40° C., 40-60° C., 60-80° C., 80-100° C., 100-120° C. and 120-140° C. On the other hand, for precursors in gas form under manufacturing conditions, the high flow rate may be achieved by increasing the gas line pressures to increase the delivery pressures to values that are much higher relative to gas line pressures used in forming thin films on relatively low surface area or planar substrates and/or substrates with low (e.g., <1) aspect ratio structures. It will be appreciated that the relatively high flow rate to achieve various advantages described herein can depend on, among other things, the pumping rate, exposure time, and volume of the reactor. To achieve flow rates adapted for depositing the thin film on substrates having a high surface area and/or high aspect ratio structures, the temperature and or pressure of the precursor, among other parameters, can be adjusted such that the flow rate of each of the V and N precursors can be, e.g., 100-1000 standard cubic centimeters per minute (sccm), 1000-2000 sccm, 2000-5000 sccm, 5000-10,000 sccm, 10,000-15,000 sccm, 15,000-20,000 sccm, or a value in a range defined by any of these values or higher. It will be appreciated that a suitable flow rate can depend, among other things, the volume of the reactor, and some of these flow rates may be suitable for single wafer reactors having a volume of about 1-2 liters.

According to embodiments, a method depositing a vanadium nitride thin film comprises providing a thin film deposition system comprising a vanadium precursor delivery line connected to a vanadium precursor source comprising a canister including a liquid vanadium precursor and a gas including vaporized vanadium precursor and a carrier gas, wherein the vanadium precursor delivery line comprises a metering valve limiting a flow of the gas to a thin film deposition chamber. The method additionally includes alternatingly exposing a substrate to the vaporized vanadium precursor and a nitrogen precursor to deposit the vanadium nitride thin film. An exposure condition for the vanadium precursor comprises: a chamber pressure inside the thin film deposition chamber of 1-10 Torr; a substrate temperature of 300-800° C.; an exposure duration to the gas including the vaporized vanadium precursor of 20 ms to 2 s; a flow rate of the carrier gas greater than 100 sccm; and a flow coefficient (Cᵥ) of the metering valve set to a value greater than 0.002.

According to embodiments, the vanadium precursor source comprising a canister including a liquid vanadium precursor can be heated to a temperature of 30-150° C., and the flow rate of the carrier gas is greater than 200 sccm. In some embodiments, the exposure duration to the gas including the vaporized vanadium precursor is 500 ms to 2 seconds. In some embodiments, the exposure condition for the vaporized vanadium precursor further comprises a partial pressure of Cl₂ in the thin film deposition chamber resulting from a decomposition of the liquid vanadium precursor that is less than 1 mTorr.

Thus, vanadium nitride thin films formed according to embodiments exhibit excellent characteristics.

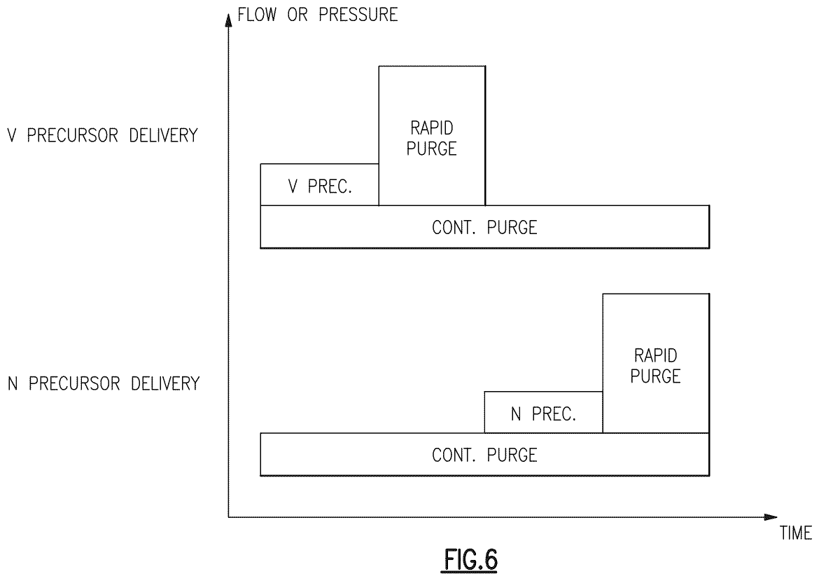

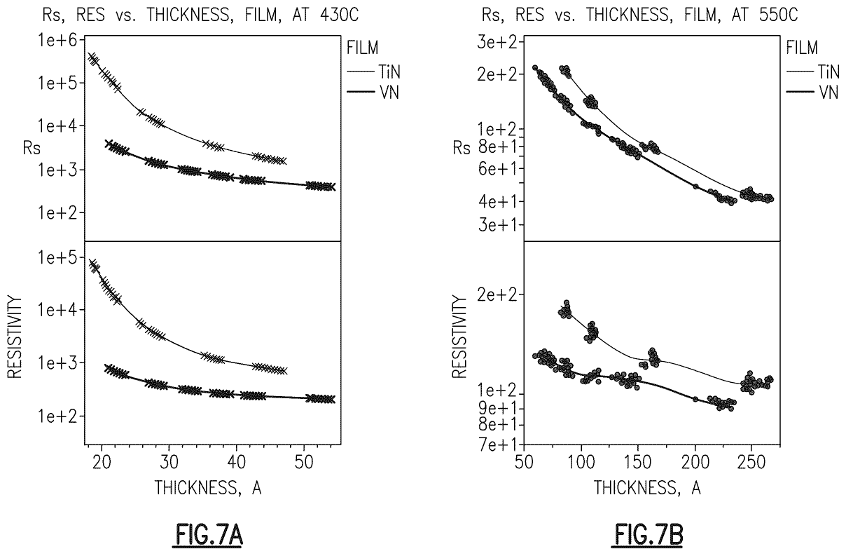

FIG. 7A is an experimental graph of thickness-dependent resistivity and sheet resistance of a vanadium nitride thin film deposited at 430° C., according to embodiments. FIG. 7B is an experimental graph of thickness-dependent resistivity and sheet resistance of a vanadium nitride thin film deposited at 550° C., according to embodiments. Relative to TiN having comparable thickness, VN thin films show substantially lower resistivity and sheet resistances. For ultrathin films, e.g., less than 3 nm, the resistivities and sheet resistances of VN thin films can be an order of magnitude or more lower relative to those of TiN. These properties are important for advanced technology nodes, where thicknesses can scale to few nanometers at most.

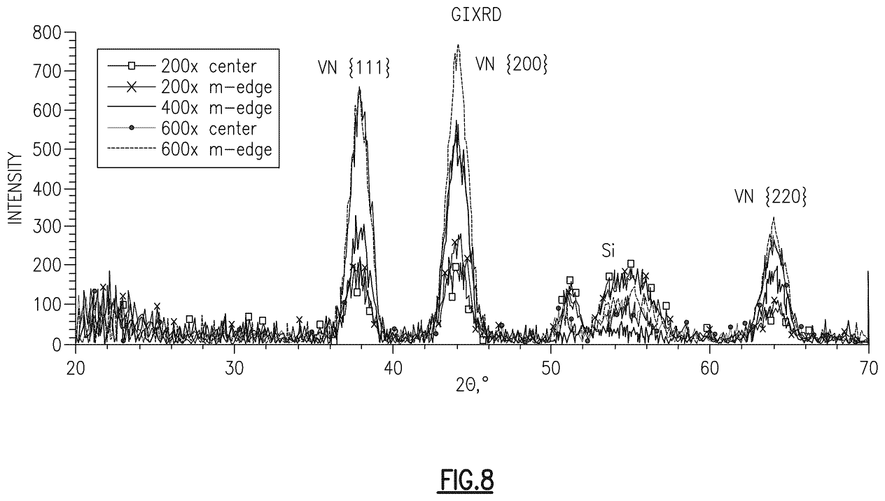

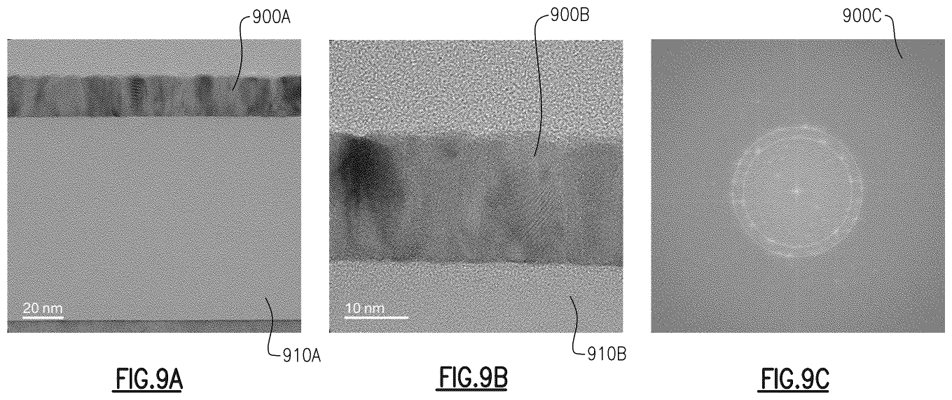

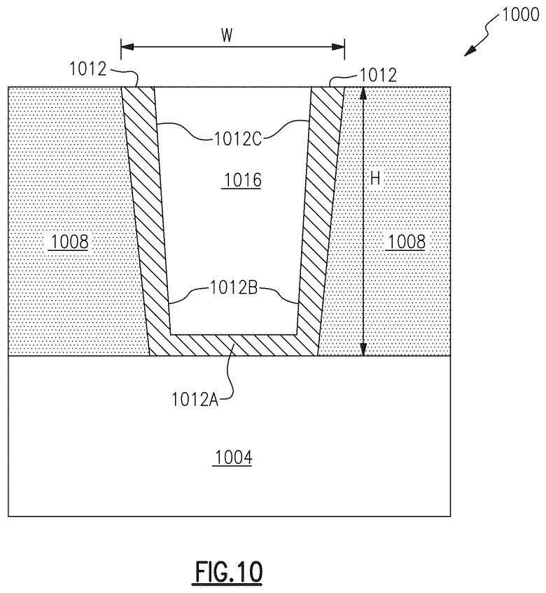

FIG. 8 is a grazing incidence X-ray diffraction spectra of a vanadium nitride thin film deposited according to embodiments, measured at various substrate locations showing face-centered cubic crystal structure of the thin film. FIGS. 9A-9C shows vanadium nitride thin films with high crystallinity and columnar structure. FIG. 9A shows a lower magnification cross-sectional transmission electron micrograph of a vanadium nitride thin film 900A deposited on SiO₂ 910A according to embodiments. FIG. 9B shows a high resolution cross sectional transmission electron micrograph of a vanadium nitride thin film 900B deposited on SiO₂ 910B according to embodiments. FIG. 9C shows a Fourier transform of a dark field transmission electron micrograph of a vanadium nitride thin film 900C deposited according to embodiments.

One measure of conformality in the context of high aspect ratio structures is referred to herein as step coverage. A high aspect ratio structure may be, e.g., a via, a hole, a trench, a cavity or a similar structure. By way of an illustrative example, FIG. 10 schematically illustrates a semiconductor structure or device 1000 having an example high aspect ratio structure 1016 formed therein, to illustrate some example metrics of defining and/or measuring conformality of thin films formed on high aspect ratio structures. The illustrated high aspect ratio structure 1016 is lined with a thin film 1012, e.g., VN layer deposited according to embodiments, having different thicknesses at different portions thereof. As described herein, a high aspect ratio structure has an aspect ratio, e.g., a ratio defined as a depth or height (H) divided by a width (W) at the opening region of the high aspect ratio structure 1016, that exceeds 1. In the illustrated example, the high aspect ratio structure 1016 is a via formed through a dielectric layer 1008, e.g., an intermetal dielectric (ILD) layer, formed on a semiconductor substrate 1004, such that a bottom surface of the high aspect ratio structure 1016 exposes the underlying semiconductor substrate 1004. The thin film 1012 can coat different surfaces of the high aspect ratio structure 1016 with different thicknesses. As described herein, one metric for defining or measuring the conformality of a thin film formed in a high aspect ratio is referred to as step coverage. A step coverage may be defined as a ratio between a thickness of a thin film at a lower or bottom region of a high aspect ratio structure and a thickness of the thin film at an upper or top region of the high aspect ratio structure. The upper or top region may be a region of the high aspect ratio structure at a relatively small depth at, e.g., 0-10% or 0-25% of the H measured from the top of the opening. The lower or bottom region may be a region of the high aspect ratio structure at a relatively high depth at, e.g., 90-100% or 75-100% of the H measured from the top of the opening. In some high aspect ratio structures, a step coverage may be defined or measured by a ratio of thicknesses of the thin film 1012A formed at a bottom surface to the thin film 1012C formed at upper or top sidewall surfaces of the high aspect ratio structure. However, it will be appreciated that some high aspect ratio structures may not have a well-defined bottom surface or a bottom surface having small radius of curvature. In these structures, a step coverage may be more consistently defined or measured by a ratio of thicknesses of the thin film 1012B formed at a lower or bottom sidewall surface to the thin film 1012C formed at an upper or top sidewall surfaces of the high aspect ratio structure.

The precursor delivery system according to embodiments, at least in part due to the relatively stable pressure inside the precursor delivery lines, gives rise to substantial improvement in step coverage in high aspect ratio structures. By employing the gas delivery lines having high conductance line portions with ALD valves, high aspect ratio structures having an aspect ratio exceeding 1, 2, 5, 10, 20, 50, 100, 200 or a value in a range defined by any of these values may be conformally coated with a thin film such as a VN film according to embodiments with a step coverage as defined herein that exceeds 70%, 80%, 90%, 95%, or has a value in a range defined by any of these values. Thus, obtained step coverage values obtained represent an improvement over corresponding step coverage values obtained using a comparable thin film deposition system having gas delivery lines without the high conductance line portions by 5%, 10%, 15%, 20% or a value in a range defined by any of these values.

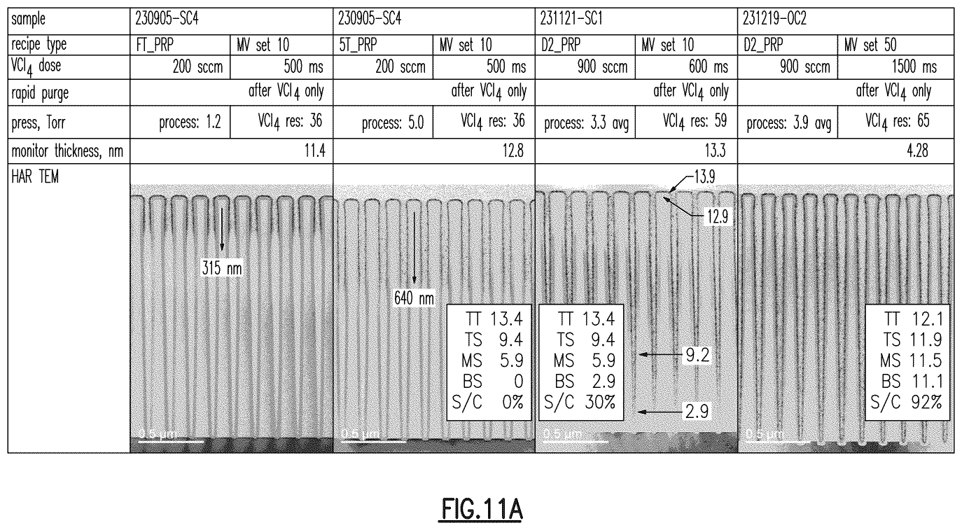

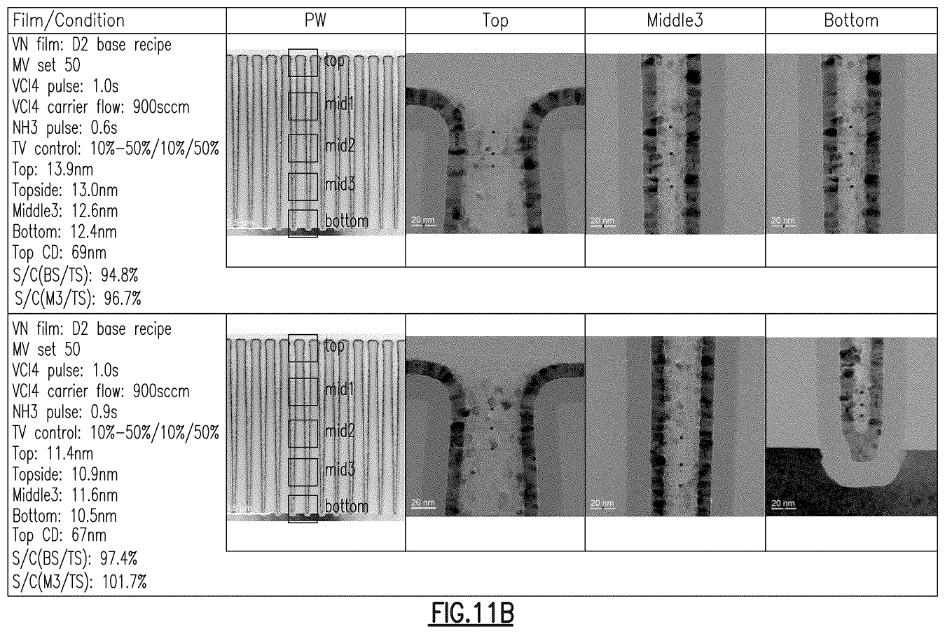

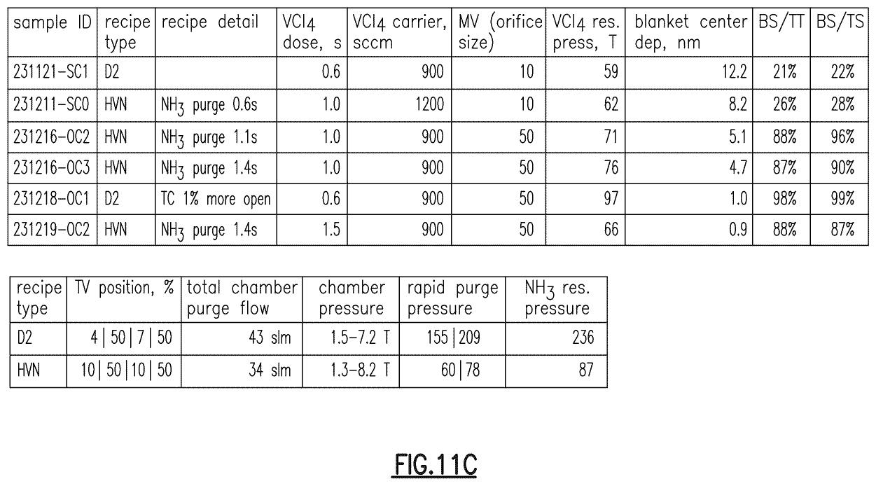

FIG. 11A illustrates cross-sectional transmission micrographs of vanadium nitride thin film deposited in high aspect ratio structures at various process conditions, according to embodiments. FIG. 11B illustrates cross-sectional transmission micrographs of vanadium nitride thin film deposited in high aspect ratio structures at various process conditions and corresponding step coverage values, according to embodiments. FIG. 11C is a summary table of measured step coverage values of vanadium nitride thin film deposited in high aspect ratio structures for various process conditions, according to embodiments. As described above, critical parameters for step coverage include the flow parameter of the metering valve (e.g., Cᵥ>0.002), carrier gas flow rate for vanadium precursor (e.g., >200 sccm), chamber pressure during vanadium exposure (e.g., >3 Torr), vanadium exposure time (e.g., >500 ms), and high conductance reservoir pressure (e.g., >40 Torr).

### Applications

The thin films comprising VN formed using different exposure pressures according to various embodiments disclosed herein can be used in a variety of applications, particularly where the substrate comprises a relatively high aspect ratio structures and/or a non-metal surface that can benefit from various advantageous characteristics of the VN layer as disclosed herein. Example applications include deposition within a via, a hole, a trench, a cavity or a similar structure having an aspect ratio, e.g., a ratio defined as a depth divided by a top width, that exceeds 1, 2, 5, 10, 20, 50, 100, 200 or a value in a range defined by any of these values.

By way of example, FIG. 10 schematically illustrates an application in the context of a diffusion barrier for a contact structure, e.g., a source or drain contact, formed on an active semiconductor substrate region that may be heavily doped. A portion of a semiconductor device 1000 is illustrated, which includes a substrate 1004 on which a dielectric layer 1008, e.g., an interlayer or intermetal dielectric (ILD) layer comprising a dielectric material such as an oxide or nitride is formed. In order to form contacts to various regions of the substrate 1004, including various doped regions, e.g., source and drain regions, a via or a trench may be formed through the dielectric layer 1008. The via or the trench may expose various non-metal surfaces, e.g., an exposed bottom surface comprising a substrate surface, e.g., a silicon substrate surface, as well as dielectric sidewalls of the vias. The bottom and side surfaces of the via can be conformally coated with a VN layer. Thereafter, the lined via may be filled with a metal, e.g., W, Al or Cu, to form a contact plug. For example, the via may be filled with tungsten by CVD using, e.g., WF₆.

The barrier layer 1012 formed according to embodiments can be advantageous for various reasons. In particular, due to the conformal nature of the barrier layer 1012 formed by ALD, the propensity for a pinching off during the subsequent metal fill process may be substantially reduced. In addition, as described above, the barrier layer 1012 can provide effective hindrance of material transport thereacross, e.g., dopant (B, P) out-diffusion from the substrate 1004, as well as in-diffusion of reactants, etchants and metals (e.g., F, Cl, W or Cu) from the contact plug formation process. The barrier effect may be enhanced by reduced surface roughness and increased step coverage. Furthermore, a layer-by-layer growth mode obtained according to embodiments may reduce the overall contact resistance of the barrier layer 1012. Furthermore, due to the reduced film roughness, a relatively thinner barrier layer 1012 may be formed while still accomplishing its desired barrier function, leading to further reduction in contact resistance.

Other applications of the VN layers formed according various embodiments disclosed herein include conductive structures formed in recessed substrates (e.g., buried electrodes or lines), electrodes (e.g., DRAM capacitor electrodes or gate electrodes), metallization barriers for higher metal levels (e.g., barriers in vias/trenches for Cu contacts/lines), high aspect ratio vertical rod electrodes or vias for three-dimensional memory and through-silicon vias (TSVs), to name a few.

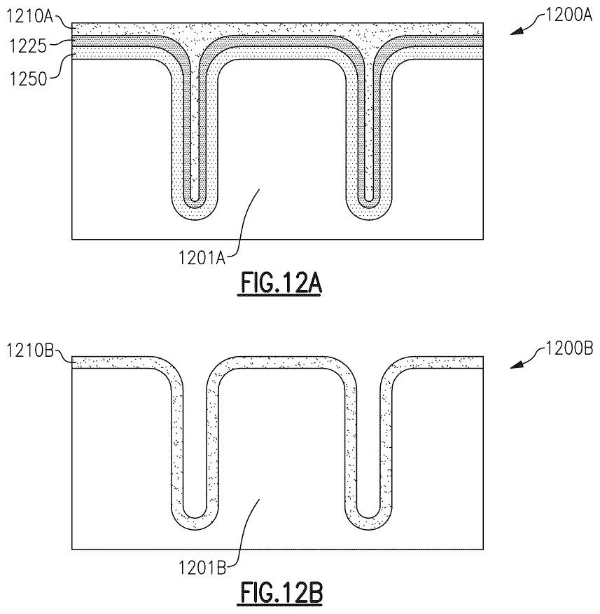

When the VN thin films disclosed herein implemented as DRAM capacitor electrodes, the VN thin films may line insides of holes. FIG. 12A schematically illustrates cross-sectional view of a vanadium nitride thin film 1210A formed as a top electrode of a capacitor 1200A, according to embodiments. As shown in FIG. 12A, a high-k dielectric material 1225 is disposed between the vanadium nitride thin film 1210A and the bottom electrode 1250 with respect to a capacitor substrate 1201A. FIG. 12B schematically illustrates a cross-sectional view of a vanadium nitride thin film 1210B formed as a bottom electrode of a capacitor 1200B with respect to a capacitor substrate 1201B, according to embodiments. The implementation as a top electrode is particularly challenging because the narrow opening would be further narrowed by the capacitor dielectric which, depending on the high-k dielectric material used, can have physical thickness exceeding 5 nm. Further, because of the underlying high-k dielectric layer, the temperature may be limited to less than, e.g., 400-450° C. Aspect ratios can be very high, as discussed above.

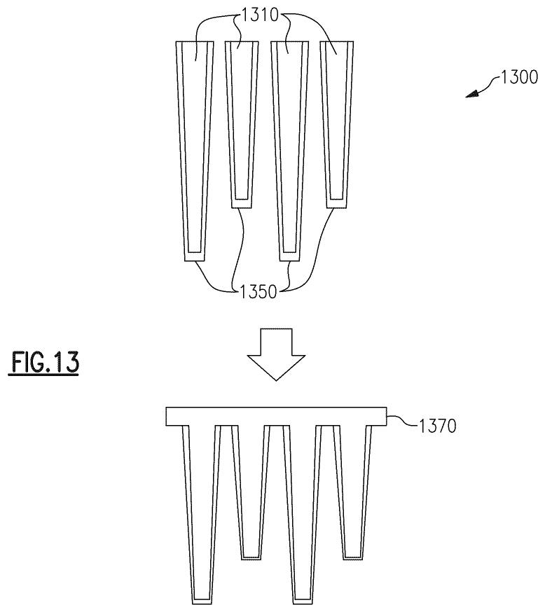

When the VN thin films disclosed herein are used as DRAM buried wordlines, the thin films may line narrow trenches. FIG. 13 schematically illustrates a cross-sectional view of a vanadium nitride thin film 1300 formed as buried wordlines 1370, according to embodiments. As shown in FIG. 13, VN fills the buried wordline trenches 1310 after formation of gate oxides 1350. Similar to top capacitor electrode applications, the buried wordline may be formed on a dielectric material which serves as a gate dielectric.

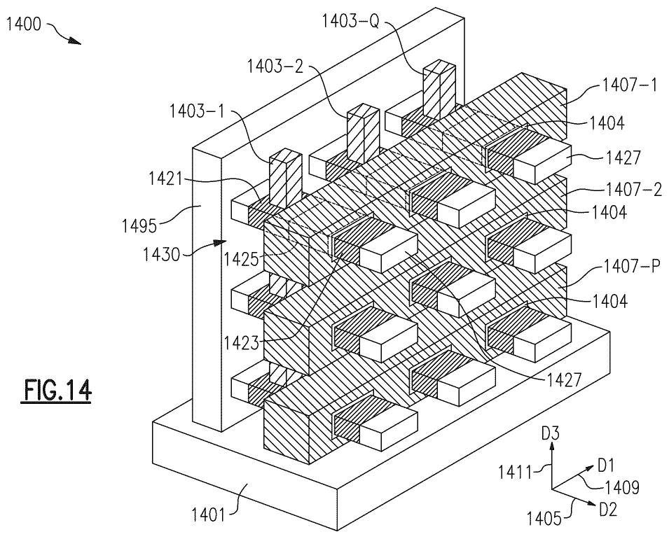

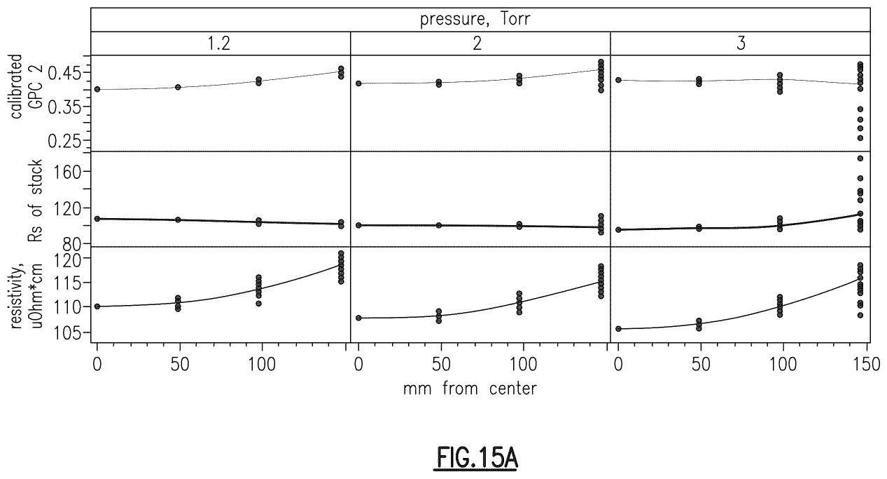

Further applications of the VN thin films include high aspect ratio vias. FIG. 14 schematically illustrates one such application, in the context of a three-dimensional memory structure, e.g., a 3D DRAM array structure, in which high aspect ratio bitlines 1403-1, 1403-2, . . . , 1403-Q extending in a D3 direction 1411 with respect to a substrate 1401 contacting source/drain regions 1421, 1423 separated by a channel region 1425 extending laterally in a D2 direction 1405 of multiple layers of access transistors 1430 in a three-dimensional memory structure are formed of highly conformal and low resistivity VN, according to embodiments. Access lines 1407-1, 1407-2, . . . , 1407-P extend in a D1 direction 1409 electrically coupled to the channel region 1425 separated by dielectrics 1404, according to embodiments.

### Impact of Rapid Purge on VN Thin Film Within-Wafer Uniformity

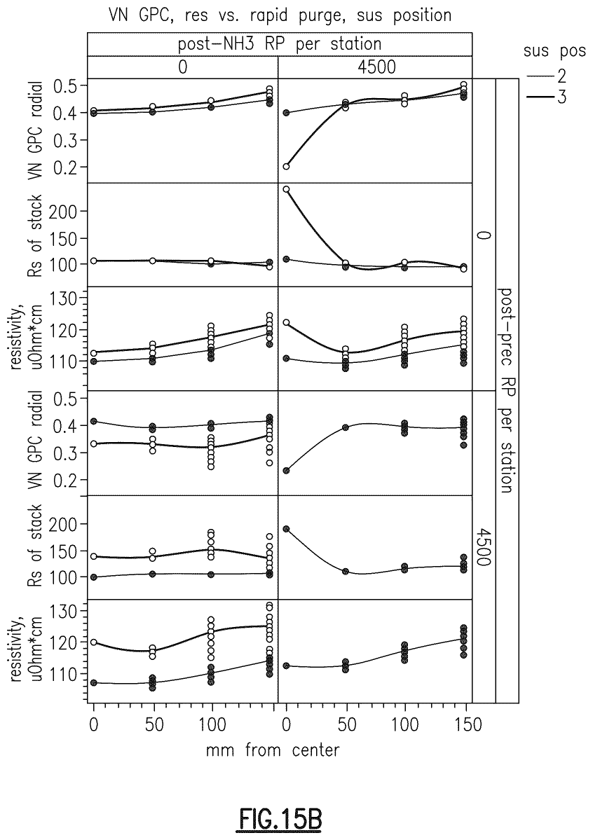

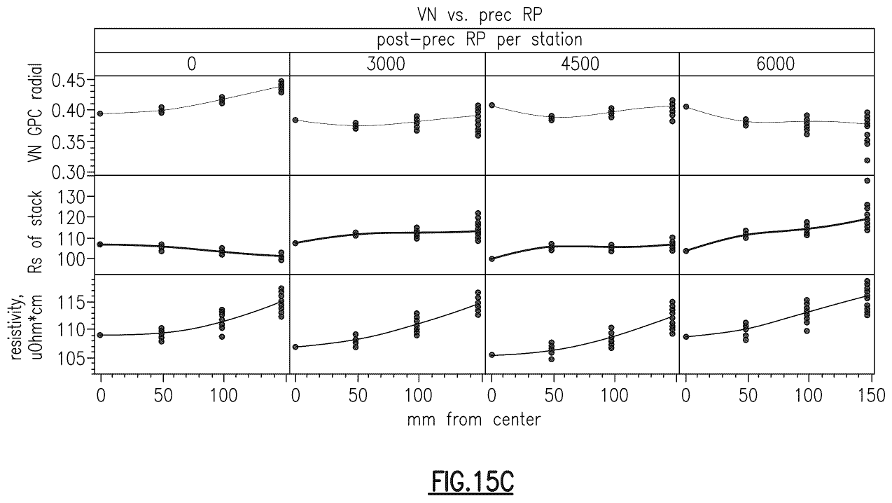

FIG. 15A shows experimental measurements related to impact of pressure without rapid purge on within-wafer uniformity for VN thin films, according to embodiments. FIG. 15A includes pressure splits without rapid purge and shows that increasing pressure decreases radial symmetry.

FIGS. 15B and 15C show experimental measurements related to impact of rapid purge on within-wafer uniformity for VN thin films, according to embodiments. FIG. 15B includes separate splits for rapid purge after each precursor dose at different susceptor positions splits and shows that resistivity increases at distances closer to the showerhead. FIG. 15C includes post-precursor rapid purge splits and shows that increasing purge flow increases center deposition relative to the edge of the wafer, decreases radial uniformity, and increases resistivity at the wafer edge.

### Additional Embodiments

Additional embodiments of methods of depositing vanadium nitride thin films are disclosed below under the headings EXAMPLE EMBODIMENTS I-III.

### Example Embodiments I

1. A method of depositing a vanadium nitride thin film, the method comprising:
   providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
   conditioning the vanadium precursor source, without a substrate in a thin film deposition chamber, by controllably removing a portion of the volume of gas in the canister by sequentially opening the first and second valves;
   disposing the substrate in the thin film deposition chamber; and
   alternatingly exposing the substrate to the vaporized vanadium precursor and a nitrogen precursor.
2. A method of depositing a vanadium nitride thin film, the method comprising:
   providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
   conditioning the vanadium precursor source, without a substrate in a thin film deposition chamber, by controllably removing a portion of the volume of gas in the canister such that a partial pressure of Cl₂ in the thin film deposition chamber resulting from a decomposition of the liquid vanadium precursor is less than 1 mTorr;
   disposing the substrate in the thin film deposition chamber; and
   alternatingly exposing the substrate to the vaporized vanadium precursor and a nitrogen precursor.
3. A method of depositing a vanadium nitride thin film, the method comprising:
   providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
   conditioning the vanadium precursor source, without a substrate in a thin film deposition chamber, by controllably removing a portion of the volume of gas in the canister that has not been used for deposition for at least one day;
   disposing the substrate in the thin film deposition chamber; and
   alternatingly exposing the substrate to the vaporized vanadium precursor and a nitrogen precursor.
4. A method of depositing a vanadium nitride thin film, the method comprising:
   providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
   conditioning the vanadium precursor source, without a substrate in a thin film deposition chamber, by controllably removing a portion of the volume of gas in a plurality of steps, wherein each step removes a sub-portion of the portion of the volume;
   disposing the substrate in a thin film deposition chamber; and
   alternatingly exposing the substrate to the vaporized vanadium precursor and a nitrogen precursor.
5. A method of depositing a vanadium nitride thin film, the method comprising:
   providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
   conditioning the vanadium precursor source, without a substrate in a thin film deposition chamber, by controllably removing a portion of the volume of gas in the canister while monitoring one or both of a pressure and a composition of the volume of gas;
   disposing the substrate in a thin film deposition chamber; and
   alternatingly exposing the substrate to the vaporized vanadium precursor and a nitrogen precursor.
6. The method of Embodiment 1, wherein conditioning is such that a partial pressure of Cl₂ in the thin film deposition chamber resulting from a decomposition of the liquid vanadium precursor is less than 1 mTorr.
7. The method of Embodiment 1, wherein the canister has not been used for deposition for at least one day.
8. The method of Embodiment 1, wherein controllably removing a portion of the volume of gas comprises removing in a plurality of steps, wherein each step removes a sub-portion of the portion of the volume.
9. The method of Embodiment 1, wherein controllably removing the portion of the volume of gas in the canister is performed while monitoring one or both of a pressure and a composition of the volume of gas.
10. The method of Embodiment 2, wherein conditioning comprises controllably removing a portion of the volume of gas in the canister by sequentially opening the first and second valves.
11. The method of Embodiment 2, wherein the canister has not been used for deposition for at least one day.
12. The method of Embodiment 2, wherein controllably removing a portion of the volume of gas comprises removing in a plurality of steps, wherein each step removes a sub-portion of the portion of the volume.
13. The method of Embodiment 2, wherein controllably removing the portion of the volume of gas in the canister is performed while monitoring one or both of a pressure and a composition of the volume of gas.
14. The method of Embodiment 3, wherein conditioning comprises controllably removing a portion of the volume of gas in the canister by sequentially opening the first and second valves.
15. The method of Embodiment 3, wherein conditioning is such that a partial pressure of Cl₂ in the thin film deposition chamber resulting from a decomposition of the liquid vanadium precursor is less than 1 mTorr.
16. The method of Embodiment 3, wherein controllably removing a portion of the volume of gas comprises removing in a plurality of steps, wherein each step removes a sub-portion of the portion of the volume.
17. The method of Embodiment 3, wherein controllably removing the portion of the volume of gas in the canister is performed while monitoring one or both of a pressure and a composition of the volume of gas.
18. The method of Embodiment 4, wherein conditioning comprises controllably removing a portion of the volume of gas in the canister by sequentially opening the first and second valves.
19. The method of Embodiment 4, wherein conditioning is such that a partial pressure of Cl₂ in the thin film deposition chamber resulting from a decomposition of the liquid vanadium precursor is less than 1 mTorr.
20. The method of Embodiment 4, wherein the canister has not been used for deposition for at least one day.
21. The method of Embodiment 4, wherein controllably removing the portion of the volume of gas in the canister is performed while monitoring one or both of a pressure and a composition of the volume of gas.
22. The method of Embodiment 5, wherein conditioning comprises controllably removing a portion of the volume of gas in the canister by sequentially opening the first and second valves.
23. The method of Embodiment 5, wherein conditioning is such that a partial pressure of Cl₂ in the thin film deposition chamber resulting from a decomposition of the liquid vanadium precursor is less than 1 mTorr.
24. The method of Embodiment 5, wherein the canister has not been used for deposition for at least one day.
25. The method of Embodiment 5, wherein controllably removing a portion of the volume of gas comprises removing in a plurality of steps, wherein each step removes a sub-portion of the portion of the volume.
26. The method of any of the above Embodiments, wherein the method is further in accordance with any of the Embodiments in EXAMPLE EMBODIMENTS II and/or EXAMPLE EMBODIMENTS III.
27. The method of any of the above Embodiments, wherein the liquid vanadium precursor comprises VCl₄ in liquid form and the volume of gas further comprises Cl₂ resulting from a decomposition of VCl₄ in the canister for at least one day.
28. The method of any of the above Embodiments, wherein the nitrogen precursor comprises NH₃.
29. The method of any of the above Embodiments, wherein the first valve is closer to the vanadium precursor source and the second valve is farther from the vanadium precursor source relative to the first valve, and wherein conditioning comprises opening the first valve while keeping the second valve closed, followed by closing the first valve to enclose the portion of the volume of gas between the first and second valves, followed by opening the second valve while keeping the first valve closed to pump out the portion of the volume of gas through a foreline.
30. The method of any of the above Embodiments, wherein the first valve is closer to the vanadium precursor source and the second valve is farther from the vanadium precursor source relative to the first valve, wherein the method further comprises monitoring one or both of a pressure and a concentration of the gas between the first and second valves with the second valve closed.
31. The method of any of the above Embodiments, wherein the vanadium precursor comprises VCl₄ and the concentration measured within the enclosed volume includes one or both of VCl₄ and Cl₂ concentrations.
32. The method of any of the above Embodiments, wherein controllably removing the portion of the volume of gas comprises sequentially opening the first and second valves a plurality of times.
33. The method of any of the above Embodiments, wherein controllably removing the portion of the volume of gas comprises removing until a pressure of less than 100 Torr is detected between the first and second valves.
34. The method of any of the above Embodiments, wherein controllably removing the portion of the volume of gas comprises removing until a pressure less than 10% of an initial pressure prior to controllably removing the volume of gas.
35. The method of any of the above Embodiments, wherein controllably removing the portion of the volume of gas comprises removing until a predetermined partial pressure of Cl₂ is detected between the first and second valves.
36. The method of any of the above Embodiments, wherein controllably removing the portion of the volume of gas comprises removing until a partial pressure of Cl₂ is less than 10% of an initial partial pressure of Cl₂ prior to controllably removing the volume of gas.
37. The method of any of the above Embodiments, wherein controllably removing the portion of the volume of gas comprises removing until a predetermined composition is detected.
38. The method of any of the above Embodiments, wherein controllably removing the portion of the volume of gas comprises removing until a predetermined concentration of VCl₄ is detected.
39. The method of any of the above Embodiments, wherein controllably removing the portion of the volume of gas comprises removing until a predetermined concentration of Cl2 is detected.
40. The method of any of the above Embodiments, wherein controllably removing the portion of the volume of gas comprises removing until a partial pressure of Cl₂ in the thin film deposition chamber resulting from a decomposition of the liquid vanadium precursor is less than 0.25 mTorr.
41. The method of any of the above Embodiments, wherein the canister is a newly installed canister.

### Example Embodiments II

1. A method of depositing a vanadium nitride thin film, the method comprising:
   providing a thin film deposition system comprising a high conductance reservoir portion as part of a vanadium precursor delivery line connected to a vanadium precursor source comprising a canister including a liquid vanadium precursor and a volume of gas including vaporized vanadium precursor,
   wherein the high conductance reservoir portion is elongated in a flow direction and has a conductance that is at least four times greater than either of immediately adjacent low conductance line portions connected at opposing ends of the high conductance reservoir portion; and
   alternatingly exposing a substrate in a thin film deposition chamber to the vaporized vanadium precursor and a nitrogen precursor,
   wherein exposing the substrate to the vaporized vanadium precursor comprises pressurizing the high conductance reservoir portion of with a final valve closed, and opening the final valve for a duration and at a flow rate such that a pressure within the high conductance reservoir portion falls by less than 10% relative to the pressure within the high conductance reservoir portion prior to opening the final valve.
2. A method of depositing a vanadium nitride thin film, the method comprising:
   providing a thin film deposition system comprising a high conductance reservoir portion as part of a vanadium precursor delivery line connected to a vanadium precursor source comprising a canister including a liquid vanadium precursor and a volume of gas including vaporized vanadium precursor,
   wherein the high conductance reservoir portion is elongated in a flow direction and comprises a pressure gauge for monitoring the pressure therein; and
   alternatingly exposing a substrate in a thin film deposition chamber to the vaporized vanadium precursor and a nitrogen precursor,
   wherein exposing the substrate to the vaporized vanadium precursor comprises pressurizing the high conductance reservoir portion to a pressure exceeding 30 Torr with a final valve closed, and opening the final valve to expose the substrate to the vaporized vanadium precursor.
3. A method of depositing a vanadium nitride thin film, the method comprising:
   providing a thin film deposition system comprising a high conductance reservoir portion as part of a vanadium precursor delivery line connected to a vanadium precursor source comprising a canister including a liquid vanadium precursor and a volume of gas including vaporized vanadium precursor,
   wherein the high conductance reservoir portion is elongated in a flow direction and comprises a gas composition monitor; and
   alternatingly exposing a substrate in a thin film deposition chamber to the vaporized vanadium precursor and a nitrogen precursor,
   wherein exposing the substrate to the vaporized vanadium precursor comprises measuring a concentration of one or more gas species in the high conductance reservoir portion with a final valve closed, and opening the final valve to expose the substrate to the vaporized vanadium precursor upon determining that the concentration is within a threshold range.
4. The method of Embodiment 1, wherein exposing the substrate to the vaporized vanadium precursor comprises pressurizing the high conductance reservoir portion to a pressure exceeding 50 Torr with the final valve closed, and opening the final valve to expose the substrate to the vaporized vanadium precursor.
5. The method of Embodiment 1, wherein exposing the substrate to the vaporized vanadium precursor comprises measuring a concentration of one or more gas species in the high conductance reservoir portion with the final valve closed, and opening the final valve to expose the substrate to the vaporized vanadium precursor upon determining that the concentration is within a threshold range.
6. The method of Embodiment 2, wherein exposing the substrate to the vaporized vanadium precursor comprises pressurizing the high conductance reservoir portion of with the final valve closed, and opening the final valve for a duration and at a flow rate such that a pressure within the high conductance reservoir portion falls by less than 10% relative to the pressure within the high conductance reservoir portion prior to opening the final valve.
7. The method of Embodiment 2, wherein exposing the substrate to the vaporized vanadium precursor comprises measuring a concentration of one or more gas species in the high conductance reservoir portion with the final valve closed, and opening the final valve to expose the substrate to the vaporized vanadium precursor upon determining that the concentration is within a threshold range.
8. The method of Embodiment 3, wherein exposing the substrate to the vaporized vanadium precursor comprises pressurizing the high conductance reservoir portion to a pressure exceeding 50 Torr with the final valve closed, and opening the final valve to expose the substrate to the vaporized vanadium precursor.
9. The method of Embodiment 3, wherein exposing the substrate to the vaporized vanadium precursor comprises pressurizing the high conductance reservoir portion of with the final valve closed, and opening the final valve for a duration and at a flow rate such that a pressure within the high conductance reservoir portion falls by less than 10% relative to the pressure within the high conductance reservoir portion prior to opening the final valve.
10. The method of any of the above Embodiments, wherein the method is further in accordance with any of the Embodiments in EXAMPLE EMBODIMENTS I and/or EXAMPLE EMBODIMENTS III.
11. The method of any of the above Embodiments, wherein the liquid vanadium precursor comprises VCl₄ in liquid form and the volume of gas further comprises Cl₂ resulting from a decomposition of VCl₄ in the canister for at least one day.
12. The method of any of the above Embodiments, wherein the nitrogen precursor comprises NH₃.
13. The method of any of the above Embodiments, wherein the first precursor pressure of the high conductance reservoir portion of the vanadium precursor line prior to opening the respective final valve is greater than 50 and less than 100 Torr.
14. The method of any of the above Embodiments, wherein the volume of the high conductance reservoir portion is such that upon opening the final valve, the pressure within the high conductance reservoir portion falls by less than 20 Torr.
15. The method of any of the above Embodiments, wherein a standard deviation of a pressure within the high conductance reservoir portion throughout a plurality of deposition cycles each including alternatingly exposing a substrate in a thin film deposition chamber to the vaporized vanadium precursor and a nitrogen precursor is less than 10% relative to a mean pressure within a same time duration.
16. The method of any of the above Embodiments, wherein a drift of a mean pressure within the high conductance reservoir portion throughout a plurality of deposition cycles each including alternatingly exposing a substrate in a thin film deposition chamber to the vaporized vanadium precursor and a nitrogen precursor is less than 10% relative to a mean pressure within a same time duration.
17. The method of any of the above Embodiments, wherein the high conductance reservoir portion has a cylindrical shape having a diameter of 0.5-5 inches.
18. The method of any of the above Embodiments, wherein the high conductance reservoir portion further has length such that a volume is 0.3-5 liters.
19. The method of any of the above Embodiments, wherein the high conductance reservoir portion serves as a transient intermediate reservoir configured to store the vanadium precursor that has been vaporized in the canister prior to reaching the high conductance line portion.
20. The method of any of the above Embodiments, wherein the final valve is an atomic layer deposition (ALD) valve disposed directly above a lid of the deposition chamber.
21. The method of any of the above Embodiments, wherein during an exposure of the substate to the vaporized vanadium precursor, the final valve is activated such that the vaporized vanadium precursor continuously flows from the canister to the thin film deposition chamber through the high conductance reservoir portion without being interrupted by actuation of another valve.
22. The method of any of the above Embodiments, wherein the thin film deposition system comprises a plurality of processing stations each configured for depositing a respective thin film by alternatingly exposing a respective substrate to a same or different plurality of precursors, wherein each of the processing stations comprises:
   a gas distribution plate,
   a susceptor, and
   a lid enclosing the thin film deposition chamber.
23. The method of any one of the above Embodiments, wherein the high conductance line portion serves as a reservoir for a plurality of processing stations each configured for depositing a respective thin film by alternatingly exposing a respective substrate to a same or different plurality of precursors.
24. The method of any of the above Embodiments, wherein the liquid vanadium precursor comprises VCl₄ in liquid form and the volume of gas further comprises Cl₂ resulting from a decomposition of VCl₄ in the canister for at least one day.

### Example Embodiments III

1. A method of depositing a vanadium nitride thin film, the method comprising:
   providing a thin film deposition system comprising a vanadium precursor delivery line connected to a vanadium precursor source comprising a canister including a liquid vanadium precursor and a gas including vaporized vanadium precursor and a carrier gas, wherein the vanadium precursor delivery line comprises a metering valve limiting a flow of the gas to a thin film deposition chamber; and
   alternatingly exposing a substrate to the vaporized vanadium precursor and a nitrogen precursor to deposit the vanadium nitride thin film, wherein an exposure condition for the vanadium precursor comprises:
      a chamber pressure inside the thin film deposition chamber of 1-10 Torr,
      a substrate temperature of 300-800° C.,
      an exposure duration to the gas including the vaporized vanadium precursor of 20 ms to 2 s,
      a flow rate of the carrier gas greater than 100 sccm, and
      a flow coefficient (Cᵥ) of the metering valve set to a value greater than 0.002.
2. A method of depositing a vanadium nitride thin film, the method comprising:
   providing a thin film deposition system comprising a vanadium precursor source comprising a canister including a liquid vanadium precursor heated to a temperature of 30 to 150° C. and a gas including vaporized vanadium precursor and a carrier gas flowing therethrough; and
   alternatingly exposing a substrate to the vaporized vanadium precursor and a nitrogen precursor to deposit the vanadium nitride thin film, wherein an exposure condition for the vanadium precursor comprises:
      a chamber pressure inside the thin film deposition chamber of 1-10 Torr,
      a substrate temperature of 300-800° C., an exposure duration to the gas including the vaporized vanadium precursor of 20 ms to 2 s, and
      a flow rate of the carrier gas greater than 200 sccm.
3. A method of depositing a vanadium nitride thin film, the method comprising:
   providing a thin film deposition system comprising a vanadium precursor source comprising a canister including a liquid vanadium precursor and a gas including vaporized vanadium precursor and a carrier gas flowing therethrough; and
   alternatingly exposing a substrate to the vaporized vanadium precursor and a nitrogen precursor to deposit the vanadium nitride thin film, wherein an exposure condition for the vanadium precursor comprises:
      a chamber pressure inside the thin film deposition chamber of 1-10 Torr,
      a substrate temperature of 300-800° C.,
      an exposure duration to the gas including the vaporized vanadium precursor of 500 ms to 2 s, and
      a flow rate of the carrier gas greater than 100 sccm.
4. A method of depositing a vanadium nitride thin film, the method comprising:
   providing a thin film deposition system comprising a vanadium precursor source comprising a canister including a liquid vanadium precursor and a gas including vaporized vanadium precursor and a carrier gas flowing therethrough; and
   alternatingly exposing a substrate to the vaporized vanadium precursor and a nitrogen precursor to deposit the vanadium nitride thin film, wherein an exposure condition for the vanadium precursor comprises:
      a chamber pressure inside the thin film deposition chamber of 1-10 Torr,
      a partial pressure of Cl₂ in the thin film deposition chamber resulting from a decomposition of the liquid vanadium precursor less than 1 mTorr,
      a substrate temperature of 300-800° C.,
      an exposure duration to the gas including the vaporized vanadium precursor of 20 ms to 2 s, and
      a flow rate of the carrier gas greater than 100 sccm.
5. A method of depositing a vanadium nitride thin film, the method comprising:
   providing a thin film deposition system comprising a vanadium precursor source comprising a canister including a liquid vanadium precursor and a gas including vaporized vanadium precursor and a carrier gas flowing therethrough;
   providing in a thin film deposition chamber a patterned substrate comprising a plurality of trenches or vias having an aspect ratio exceeding 10 and an opening width smaller than 100 nm; and
   alternatingly exposing a substrate to the vaporized vanadium precursor and a nitrogen precursor to deposit the vanadium nitride thin film, wherein an exposure condition for the vanadium precursor comprises:
      a chamber pressure inside the thin film deposition chamber of 1-10 Torr,
      a substrate temperature of 300-800° C.,
      an exposure duration to the gas including the vaporized vanadium precursor of 20 ms to 2 s, and
      a flow rate of the carrier gas greater than 100 sccm, such that a step coverage, defined as a ratio of a thickness of the thin film at a lower half of a sidewall of the trenches or vias to a thickness of the thin film at an upper half of the sidewall of the high aspect ratio trench or via, that is higher than 30%.
6. The method of Embodiment 1, wherein the liquid vanadium precursor heated to a temperature of 30 to 150° C., and the flow rate of the carrier gas is greater than 200 sccm.
7. The method of Embodiment 1, wherein the exposure duration to the gas including the vaporized vanadium precursor is 500 ms to 2 seconds.
8. The method of Embodiment 1, wherein the exposure condition for the vaporized vanadium precursor further comprises a partial pressure of Cl₂ in the thin film deposition chamber resulting from a decomposition of the liquid vanadium precursor that is less than 1 mTorr.
9. The method of Embodiment 1, wherein the substrate is a patterned substrate comprising a plurality of trenches or vias having an aspect ratio exceeding 10 and an opening width smaller than 100 nm, and wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
10. The method of Embodiment 2, wherein the vanadium precursor delivery line comprises a metering valve limiting a flow of the gas to a thin film deposition chamber, wherein a flow coefficient (Cᵥ) of the metering valve set to a value greater than 0.002.
11. The method of Embodiment 2, wherein the exposure duration to the gas including the vaporized vanadium precursor is 500 ms to 2 seconds.
12. The method of Embodiment 2, wherein the exposure condition for the vaporized vanadium precursor further comprises a partial pressure of Cl₂ in the thin film deposition chamber resulting from a decomposition of the liquid vanadium precursor that is less than 1 mTorr.
13. The method of Embodiment 2, wherein the substrate us a patterned substrate comprising a plurality of trenches or vias having an aspect ratio exceeding 10 and an opening width smaller than 100 nm, and wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
14. The method of Embodiment 3, wherein the vanadium precursor delivery line comprises a metering valve limiting a flow of the gas to a thin film deposition chamber, wherein a flow coefficient (Cᵥ) of the metering valve set to a value greater than 0.002.
15. The method of Embodiment 3, wherein the liquid vanadium precursor heated to a temperature of 30 to 150° C., and the flow rate of the carrier gas is greater than 200 sccm.
16. The method of Embodiment 3, wherein the exposure condition for the vaporized vanadium precursor further comprises a partial pressure of Cl₂ in the thin film deposition chamber resulting from a decomposition of the liquid vanadium precursor that is less than 1 mTorr.
17. The method of Embodiment 3, wherein the substrate us a patterned substrate comprising a plurality of trenches or vias having an aspect ratio exceeding 10 and an opening width smaller than 100 nm, and wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
18. The method of Embodiment 4, wherein the vanadium precursor delivery line comprises a metering valve limiting a flow of the gas to a thin film deposition chamber, wherein a flow coefficient (Cᵥ) of the metering valve set to a value greater than 0.002.
19. The method of Embodiment 4, wherein the liquid vanadium precursor heated to a temperature of 30 to 150° C., and the flow rate of the carrier gas is greater than 200 sccm.
20. The method of Embodiment 4, wherein the exposure duration to the gas including the vaporized vanadium precursor is 500 ms to 2 seconds.
21. The method of Embodiment 4, wherein the substrate us a patterned substrate comprising a plurality of trenches or vias having an aspect ratio exceeding 10 and an opening width smaller than 100 nm, and wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
22. The method of Embodiment 5, wherein the vanadium precursor delivery line comprises a metering valve limiting a flow of the gas to a thin film deposition chamber, wherein a flow coefficient (Cᵥ) of the metering valve set to a value greater than 0.002.
23. The method of Embodiment 5, wherein the liquid vanadium precursor heated to a temperature of 30 to 150° C., and the flow rate of the carrier gas is greater than 200 sccm.
24. The method of Embodiment 5, wherein the exposure duration to the gas including the vaporized vanadium precursor is 500 ms to 2 seconds.
25. The method of Embodiment 5, wherein the exposure condition for the vaporized vanadium precursor further comprises a partial pressure of Cl₂ in the thin film deposition chamber resulting from a decomposition of the liquid vanadium precursor that is less than 1 mTorr.
26. The method of any of the above Embodiments, wherein the method is further in accordance with any of the Embodiments in EXAMPLE EMBODIMENTS I and/or EXAMPLE EMBODIMENTS II.
27. The method of any of the above Embodiments, wherein the liquid vanadium precursor comprises VCl₄ in liquid form and the volume of gas further comprises Cl₂ resulting from a decomposition of VCl₄ in the canister for at least one day.
28. The method of any of the above Embodiments, wherein the nitrogen precursor comprises NH₃.
29. The method of any of the above Embodiments, wherein the chamber pressure inside the thin film deposition chamber during the exposure of the substrate to the vaporized vanadium precursor is 1-5 Torr.
30. The method of any of the above Embodiments, wherein the chamber pressure inside the thin film deposition chamber during a rapid purge after the exposure of the substrate to the vaporized vanadium precursor is 5-10 Torr.
31. The method of any of the above Embodiments, wherein the chamber pressure inside the thin film deposition chamber during the exposure of the substrate to the nitrogen precursor is 1-5 Torr.
32. The method of any of the above Embodiments, wherein the chamber pressure inside the thin film deposition chamber during a rapid purge after the exposure of the substrate to the nitrogen precursor is 5-10 Torr.
33. The method of any of the above Embodiments, wherein an exposure duration to nitrogen precursor is of 0.1 s to 2 s.
34. The method of any of the above Embodiments, wherein the substrate temperature is 300-600° C.,
35. The method of any of the above Embodiments, wherein a partial pressure of Cl₂ in the thin film deposition chamber resulting from a decomposition of the liquid vanadium precursor less than 1 mTorr.
36. The method of any of the above Embodiments, wherein the substrate is a patterned substrate comprising a plurality of trenches or vias having an aspect ratio exceeding 20 and an opening width smaller than 80 nm wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
37. The method of any of the above Embodiments, wherein the substrate is a patterned substrate comprising a plurality of trenches or vias having an aspect ratio exceeding 30 and an opening width smaller than 60 nm, wherein a step coverage, defined as a ratio of a thickness of the thin film at a lower half of a sidewall of the trenches or vias to a thickness of the thin film at an upper half of the sidewall of the high aspect ratio trench or via, that is higher than 30%.
38. The method of any of the above Embodiments, wherein the substrate is a patterned substrate comprising a plurality of trenches or vias having an aspect ratio exceeding 20 and an opening width smaller than 80 nm wherein a step coverage, defined as a ratio of a thickness of the thin film at a lower half of a sidewall of the trenches or vias to a thickness of the thin film at an upper half of the sidewall of the high aspect ratio trench or via, that is higher than 70%.
39. The method of any of the above Embodiments, wherein the substrate is a patterned substrate comprising a plurality of trenches or vias having an aspect ratio exceeding 30 and an opening width smaller than 60 nm, wherein a step coverage, defined as a ratio of a thickness of the thin film at a lower half of a sidewall of the trenches or vias to a thickness of the thin film at an upper half of the sidewall of the high aspect ratio trench or via, that is higher than 70%.

### Additional Considerations

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A method of depositing a vanadium nitride thin film, the method comprising:
providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
conditioning the vanadium precursor source, without a substrate in a thin film deposition chamber, by controllably removing a portion of the volume of gas in the canister by sequentially opening the first and second valves;
disposing the substrate in the thin film deposition chamber; and
alternatingly exposing the substrate to the vaporized vanadium precursor and a nitrogen precursor.

2. The method of claim 1, wherein conditioning is such that a partial pressure of Cl2 in the thin film deposition chamber resulting from a decomposition of the liquid vanadium precursor is less than 1 mTorr.

3. The method of claim 1, wherein the canister has not been used for deposition for at least one day.

4. The method of claim 1, wherein the first valve is closer to the vanadium precursor source and the second valve is farther from the vanadium precursor source relative to the first valve, and wherein conditioning comprises opening the first valve while keeping the second valve closed, followed by closing the first valve to enclose the portion of the volume of gas between the first and second valves, followed by opening the second valve while keeping the first valve closed to pump out the portion of the volume of gas through a foreline.

5. The method of claim 1, wherein controllably removing the portion of the volume of gas comprises sequentially opening the first and second valves a plurality of times.

6. The method of claim 1, wherein controllably removing a portion of the volume of gas comprises removing in a plurality of steps, wherein each step removes a sub-portion of the portion of the volume.

7. The method of claim 1, wherein controllably removing the portion of the volume of gas in the canister is performed while monitoring one or both of a pressure and a composition of the volume of gas.

8. The method of claim 7, wherein controllably removing the portion of the volume of gas comprises removing until the pressure of less than 100 Torr is detected between the first and second valves.

9. The method of claim 7, wherein controllably removing the portion of the volume of gas comprises removing until the pressure is less than 10% of an initial pressure prior to controllably removing the volume of gas.

10. The method of claim 7, wherein controllably removing the portion of the volume of gas comprises removing until a predetermined composition is detected.

11. The method of claim 1, wherein the nitrogen precursor comprises NH₃.

12. A method of depositing a vanadium nitride thin film, the method comprising:
providing a thin film deposition system comprising a vanadium precursor delivery line comprising first and second valves disposed between a final valve and a vanadium precursor source comprising a canister including a liquid vanadium precursor and a volume of gas including vaporized vanadium precursor;
conditioning the vanadium precursor source, without a substrate in a thin film deposition chamber, by controllably removing a portion of the volume of gas in the canister such that a partial pressure of Cl₂ in the thin film deposition chamber resulting from a decomposition of the liquid vanadium precursor is less than 1 mTorr;
disposing the substrate in the thin film deposition chamber; and
alternatingly exposing the substrate to the vaporized vanadium precursor and a nitrogen precursor.

13. The method of claim 12, wherein the first valve is closer to the vanadium precursor source and the second valve is farther from the vanadium precursor source relative to the first valve, wherein the method further comprises monitoring one or both of a pressure and a concentration of the gas between the first and second valves with the second valve closed.

14. The method of claim 13, wherein controllably removing the portion of the volume of gas comprises removing until a predetermined partial pressure of Cl₂ is detected between the first and second valves.

15. The method of claim 13, wherein controllably removing the portion of the volume of gas comprises removing until the partial pressure of Cl₂ is less than 10% of an initial partial pressure of Cl₂ prior to controllably removing the volume of gas.

16. The method of claim 12, wherein controllably removing the portion of the volume of gas comprises removing until the partial pressure of Cl₂ in the thin film deposition chamber resulting from the decomposition of the liquid vanadium precursor is less than 0.25 mTorr.

17. The method of claim 13, wherein the liquid vanadium precursor comprises VCl₄ in liquid form and the volume of gas further comprises Cl₂ resulting from a decomposition of VCl₄ in the canister for at least one day.

18. The method of claim 17, wherein the concentration measured within the enclosed volume includes one or both of VCl₄ and Cl₂ concentrations.

19. The method of claim 18, wherein controllably removing the portion of the volume of gas comprises removing until a predetermined concentration of VCl₄ is detected.

20. The method of claim 18, wherein controllably removing the portion of the volume of gas comprises removing until a predetermined concentration of Cl₂ is detected.
